(19) United States
(12) Patent Application Publication
(10) Pub. No.: US 2026/0068699 A1
(43) Pub. Date: Mar. 5, 2026

(54) ELECTRONIC COMPONENT EMBEDDED SUBSTRATE AND METHOD OF MANUFACTURING THE SAME

(71) Applicant: Samsung Electronics Co., Ltd., Suwon-si (KR)

(72) Inventors: Miki TAKAHASHI, Yokohama-shi (JP); Mitsuhiro TOMIKAWA, Yokohama-shi (JP); Ryuichiro TOMINAGA, Yokohama-shi (JP); Takashi KARIYA, Yokohama-shi (JP); Toshiki FURUTANI, Yokohama-shi (JP)

(73) Assignee: Samsung Electronics Co., Ltd., Suwon-si (KR)

(21) Appl. No.: 19/240,761

(22) Filed: Jun. 17, 2025

(30) Foreign Application Priority Data
Sep. 5, 2024 (JP) 2024-152820
Jan. 20, 2025 (KR) 10-2025-0008210

(51) Int. Cl. H01L 23/538; H01L 21/48; H01L 21/683; H01L 23/00; H01L 23/31; H01L 25/18

(52) U.S. Cl. CPC H01L 23/5383

(57) ABSTRACT

An electronic component embedded substrate may include at least an electronic component including a first terminal surface and a first terminal electrode, the first terminal electrode being on the first terminal surface, a first conductive layer facing the first terminal surface, an insulating layer between the first conductive layer and the first terminal surface, the insulating layer including a via hole penetrating therethrough, the first conductive layer filling the via hole and being connected to the first terminal electrode, and a seed layer in the via hole, the seed layer including a conductive film and an adhesive film, the adhesive film being between the conductive film and a boundary of the via hole.

### CROSS-REFERENCE TO RELATED APPLICATION(S)

This application claims the benefit under 35 USC 119 (a) of Korean Patent Application No. 10-2025-0008210 filed on Jan. 20, 2025 in the Korean Intellectual Property Office, and Japanese Patent Application No. 2024-152820 filed on Sep. 5, 2024 in the Japan Patent Office, the entire contents of each of which are incorporated herein by reference for all purposes.

### BACKGROUND

The present inventive concepts relate to electronic component embedded substrates and methods of manufacturing the electronic component embedded substrate.

Recently, electronic component embedded substrates with built-in electronic components have been attracting attention. Electronic component embedded substrates function as interposers connecting semiconductor devices and mounting substrates.

### SUMMARY

Some example embodiments provide electronic component embedded substrates in which reliability of connections between conductors through via holes is improved.

According to example embodiments, an electronic component embedded substrate may include at least one electronic component including a first terminal surface and a first terminal electrode, the first terminal electrode being on the first terminal surface, a first conductive layer facing the first terminal surface, an insulating layer between the first conductive layer and the first terminal surface, the insulating layer including a via hole penetrating therethrough, the first conductive layer filling the via hole and being connected to the first terminal electrode, and a seed layer in the via hole, the seed layer including a conductive film and an adhesive film, the adhesive film being between the conductive film and a boundary of the via hole.

The electronic component embedded substrate may further include a metal film between the first conductive layer and the insulating layer, wherein the metal film includes a through-hole defined therethrough and fluidly connected to the via hole.

In the electronic component embedded substrate, the seed layer may further be provided in the through-hole.

In the electronic component embedded substrate, the seed layer may include a first portion on a surface of the metal film and a second portion connected to the first portion and being along a boundary of the through hole and the boundary of the via hole.

In the electronic component embedded substrate, the adhesive film may be provided from the surface of the metal film to an outer side of an edge of the metal film.

In the electronic component embedded substrate, the conductive film may include copper (Cu) and the adhesive film may include titanium (Ti).

In the electronic component embedded substrate, at least one of the conductive film or the adhesive film may include a sputtered film.

In the electronic component embedded substrate, the adhesive film may defines the boundary of the via hole.

In the electronic component embedded substrate, a hole diameter of the via hole may be substantially uniform across a thickness direction of the insulating layer.

In the electronic component embedded substrate, a thickness of each of the conductive film and the adhesive film may increase towards the first terminal electrode.

In the electronic component embedded substrate, the insulating layer may include an organic insulating material.

In the electronic component embedded substrate, the electronic component embedded substrate may further have a second conductive layer, the electronic component may further have a second terminal surface opposing the first terminal surface and a second terminal electrode is on the second terminal surface, and the second terminal electrode may be electrically connected to the second conductive layer.

The electronic component embedded substrate the at least one electronic component may include a plurality of the electronic components.

In the electronic component embedded substrate, the plurality of electronic components may include electronic components having different thicknesses from each other.

According to example embodiments, a method of manufacturing an electronic component embedded substrate may include providing an adhesive layer on a support substrate, attaching an electronic component to the support substrate such that a terminal surface of the electronic component, which includes a terminal electrode thereon faces the support substrate with the adhesive layer interposed between the terminal surface and the support substrate facing each other, removing the support substrate, forming an opening in the adhesive layer to expose the terminal electrode therethrough, forming an adhesive film and a conductive film in order to form a seed layer in the opening, and forming a conductor electrically connected to the terminal electrode via the seed layer.

In the method of manufacturing an electronic component embedded substrate the providing the adhesive layer may include providing the adhesive layer by interposing a metal film on the support substrate, and the forming an opening includes forming a through hole in the metal film such that the opening is fluidly connected to the through hole.

In the method of manufacturing an electronic component embedded substrate the forming the adhesive film and the conductive film may include forming the adhesive film and the conductive film using a sputtering method.

In the method of manufacturing an electronic component embedded substrate, the forming the opening may include forming the opening in the adhesive layer using a dry etching method. According to an example embodiment of the present inventive concepts, an electronic component embedded substrate may include at least an electronic component including a first terminal surface and a first terminal electrode, the first terminal electrode being on the first terminal surface, a first conductive layer facing the first terminal surface, an insulating layer between the first conductive layer and the first terminal surface, the insulating layer including a via hole penetrating therethrough, the first conductive layer filling the via hole and being connected to the first terminal electrode, and a seed layer in the via hole, the seed layer including a conductive film and an adhesive film, the adhesive film being between the conductive film and a boundary of the via hole.

According to an example embodiment of the present inventive concepts, a method of manufacturing an electronic component embedded substrate may include providing an adhesive layer on a support substrate, attaching an electronic component to the support substrate such that a terminal surface of the electronic component, which includes a terminal electrode thereon faces the support substrate with the adhesive layer interposed between the terminal surface and the support substrate facing each other, removing the support substrate, forming an opening in the adhesive layer to expose the terminal electrode therethrough, forming an adhesive film and a conductive film in order to form a seed layer in the opening, and forming a conductor electrically connected to the terminal electrode via the seed layer.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a cross-sectional view illustrating an example of a configuration of an electronic device including an electronic component embedded substrate according to an example embodiment;

FIG. 2 is a cross-sectional view illustrating an enlarged view of the vicinity of a via hole illustrated in FIG. 1;

FIG. 3 is a cross-sectional view illustrating one process of a manufacturing method of an electronic device illustrated in FIG. 1;

FIG. 4 is a cross-sectional view illustrating a process continuing from FIG. 3;

FIG. 5 is a cross-sectional view illustrating a process continuing from FIG. 4;

FIG. 6 is a cross-sectional view illustrating a process continuing from FIG. 5;

FIG. 7 is a cross-sectional view illustrating a process continuing from FIG. 6;

FIG. 8 is a cross-sectional view illustrating a process continuing from FIG. 7;

FIG. 9 is a cross-sectional view illustrating a process continuing from FIG. 8;

FIG. 10 is a cross-sectional view illustrating a process continuing from FIG. 9;

FIG. 11 is a cross-sectional view illustrating a process continuing from FIG. 10;

FIG. 12 is a cross-sectional view illustrating a process continuing from FIG. 11;

FIG. 13 is a cross-sectional view illustrating a process continuing from FIG. 12;

FIG. 14 is a cross-sectional view illustrating a process continuing from FIG. 13;

FIG. 15 is a cross-sectional view illustrating a process continuing from FIG. 14;

FIG. 16 is a cross-sectional view illustrating a process continuing from FIG. 15;

FIG. 17 is a cross-sectional view illustrating a process continuing from FIG. 16;

FIG. 18 is a cross-sectional view illustrating a process continuing from FIG. 17;

FIG. 19 is a cross-sectional view illustrating a process continuing from FIG. 18;

FIG. 20 is a cross-sectional view illustrating a process continuing from FIG. 19;

FIG. 21 is a cross-sectional view illustrating a process continuing from FIG. 20;

FIG. 22 is a cross-sectional view illustrating a process continuing from FIG. 21;

FIG. 23 is a cross-sectional view illustrating a process continuing from FIG. 22;

FIG. 24 is a cross-sectional view illustrating a process continuing from FIG. 23;

FIG. 25 is a cross-sectional view illustrating a process continuing from FIG. 24;

FIG. 26 is a cross-sectional view illustrating a process continuing from FIG. 25;

FIG. 27 is a cross-sectional view illustrating a process continuing from FIG. 26;

FIG. 28 is a cross-sectional view illustrating a process continuing from FIG. 27;

FIG. 29 is a cross-sectional view illustrating a process continuing from FIG. 28;

FIG. 30 is a cross-sectional view illustrating a process continuing from FIG. 29;

FIG. 31 is a cross-sectional view illustrating a process continuing from FIG. 30;

FIG. 32 is a cross-sectional view illustrating a process continuing from FIG. 31.

FIG. 33 is a cross-sectional view illustrating a process continuing from FIG. 32;

FIG. 34 is a cross-sectional view illustrating a process continuing from FIG. 33;

FIG. 35 is a cross-sectional view illustrating a process continuing from FIG. 34;

FIG. 36 is a cross-sectional view illustrating a process continuing from FIG. 35;

FIG. 37 is a cross-sectional view illustrating a process continuing from FIG. 36;

FIG. 38 is a cross-sectional view illustrating a process continuing from FIG. 37;

FIG. 39 is a cross-sectional view illustrating a process continuing from FIG. 38;

FIG. 40 is a cross-sectional view illustrating a process continuing from FIG. 39;

FIG. 41 is a cross-sectional view illustrating a process continuing from FIG. 40;

FIG. 42 is a cross-sectional view illustrating a process continuing from FIG. 41;

FIG. 43 is a cross-sectional view illustrating a process continuing from FIG. 42;

FIG. 44 is a cross-sectional view illustrating a process continuing from FIG. 43;

FIG. 45 is a cross-sectional view illustrating a process continuing from FIG. 44;

FIG. 46 is a cross-sectional view illustrating a process continuing from FIG. 45;

FIG. 47 is a cross-sectional view illustrating a process continuing from FIG. 46;

FIG. 48 is a cross-sectional view illustrating a process continuing from FIG. 47;

FIG. 49 is a cross-sectional view illustrating a process continuing from FIG. 48;

FIG. 50 is a cross-sectional view illustrating a process continuing from FIG. 49;

FIG. 51 is a cross-sectional view illustrating a process continuing from FIG. 50;

FIG. 52 is a cross-sectional view illustrating a process continuing from FIG. 51;

FIG. 53 is a cross-sectional view illustrating a process continuing from FIG. 52;

FIG. 54 is a cross-sectional view illustrating an example of the configuration of a main part of an electronic component embedded substrate according to a modified example;

FIG. 55 is a cross-sectional view illustrating an example of the configuration of an electronic component embedded substrate according to another modified example;

FIG. 56 is a cross-sectional view illustrating an example of the configuration of an electronic component embedded substrate according to another modified example; and

FIG. 57 is a cross-sectional view illustrating an example of the configuration of an electronic component embedded substrate according to another modified example.

### DETAILED DESCRIPTION

Hereinafter, with reference to the attached drawings, some example embodiments will be described in detail. In the drawings below, the same reference numerals refer to the same components, and the sizes of respective components in the drawings may be exaggerated for clarity and convenience of explanation. In addition, the example embodiments described below are merely illustrative, and various modifications are possible from such example embodiments.

Hereinafter, the terms “upper” or “on” may include not only those directly above in contact, but also those above in a non-contact manner.

Singular expressions include plural expressions unless the context clearly indicates otherwise. In addition, when a part is said to “include” or “have” a component, it does not exclude other components unless there is a specific description to the contrary, and means that other components may be additionally included.

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the term “about,” “substantially” or “approximately” is used in this specification in connection with a numerical value, it is intended that the associated numerical value includes a manufacturing or operational tolerance (e.g., +10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

In addition, the use of the term “the” and similar descriptive terms correspond to both singular and plural.

For the steps/operations of a method, unless the order is explicitly stated or the contrary is not stated, the steps/operations are performed in the appropriate order. The order in which the steps/operations are described is not necessarily limited to the order in which they are described. The use of any example terms (for example, etc., the like) is intended merely to illustrate technical ideas and is not intended to limit the scope of the present inventive concepts, unless otherwise limited by the claims.

### EMBODIMENT

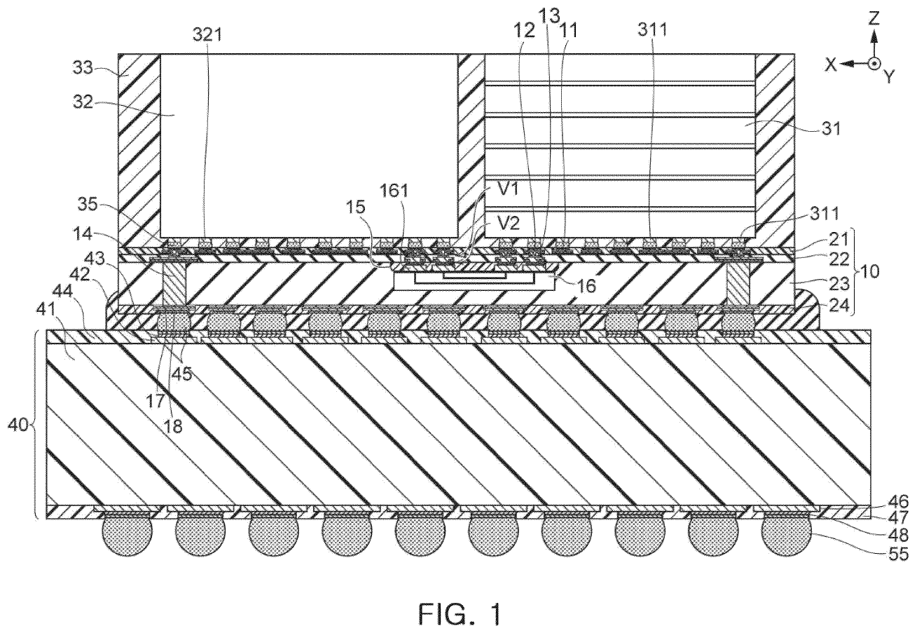

FIG. 1 illustrates an example of the configuration of an electronic device having an electronic component embedded substrate 10 according to an example embodiment. The electronic device includes, for example, as main members, an electronic component embedded substrate 10, semiconductor devices 31 and 32, and a mounting substrate 40. The electronic component embedded substrate 10 functions as an interposer connecting the semiconductor devices 31 and 32 and the mounting substrate 40. In the electronic device, the mounting substrate 40, the electronic component embedded substrate 10, and the semiconductor devices 31 and 32 are laminated in order. In the following description, the lamination direction of the mounting substrate 40, the electronic component embedded substrate 10, and the semiconductor devices 31 and 32 is sometimes referred to as the Z-direction, the direction orthogonal to the Z-direction is sometimes referred to as the X direction, and the direction orthogonal to the Z-direction and the X direction is sometimes referred to as the Y-direction.

The semiconductor devices 31 and 32 are, for example, semiconductor chips having a desired (or alternatively, predetermined) function. The semiconductor devices 31 and 32 are, for example, Integrated Circuit (IC) chips, memories, or the like. The semiconductor device 31 has, for example, a plurality of electrodes 311 on a desired (or alternatively, predetermined) surface (for example, an X-Y plane). The semiconductor device 32 has, for example, a plurality of electrodes 321 on a desired (or alternatively, predetermined) surface (for example, an X-Y plane). The electronic device additionally has, for example, an encapsulation layer 33 and a plurality of bumps 35 in the vicinity of the semiconductor devices 31 and 32.

The encapsulation layer 33 covers, for example, the periphery of the semiconductor devices 31 and 32. The plurality of bumps 35 electrically connect the respective electrodes 311 and 321 and the electronic component embedded substrate 10.

The mounting substrate 40 is, for example, a semiconductor package substrate, a motherboard, and the like. The mounting substrate 40 has, for example, a substrate 41, a first interconnection layer 42, a first electrode 43, a first solder resist layer 44, a second interconnection layer 46, a second solder resist layer 47, and a second electrode 48. The first interconnection layer 42, the first electrode 43, and the first solder resist layer 44 are provided on one main surface of the substrate 41. The second interconnection layer 46, the second solder resist layer 47, and the second electrode 48 are provided on the other main surface of the substrate 41.

The mounting substrate 40 is electrically connected to an electronic component embedded substrate 10 via a plurality of bumps 45 interposed therebetween. The plurality of bumps 45 are provided on the first electrode 43. For example, the spacing between neighboring bumps 45 is greater than the spacing between neighboring bumps 35. The plurality of second electrodes 48 are electrically connected to other members (e.g., via bumps 55), respectively. For example, the spacing between neighboring bumps 55 is greater than the spacing between neighboring bumps 45. The bumps 35, 45 and 55 include, for example, solder materials.

### (Overall Configuration of Electronic Component Embedded Substrate 10)

The electronic component embedded substrate 10 includes, for example, a first substrate electrode 11, a relay conductive layer 12, a first conductive layer 13, an adhesive layer 15, an electronic component 16, a second conductive layer 17, a second substrate electrode 18, a first solder resist layer 21, a first insulating layer 22, a second insulating layer 23, and a second solder resist layer 24. In this case, the adhesive layer 15 corresponds to a specific example of the insulating layer of the present inventive concept.

In the electronic component embedded substrate 10, along the Z-direction, the first solder resist layer 21, the first insulating layer 22, the second insulating layer 23, and the second solder resist layer 24 are laminated in order. For example, from a position close to the semiconductor devices 31 and 32, the first solder resist layer 21, the first insulating layer 22, the second insulating layer 23, and the second solder resist layer 24 are disposed in order. The first solder resist layer 21 and the second solder resist layer 24 include, for example, an organic insulating material such as epoxy resin, phenol resin, or acrylic resin. The first solder resist layer 21 and the second solder resist layer 24 may include a filler.

The first insulating layer 22 and the second insulating layer 23 each include an organic insulating material such as, for example, epoxy resin, phenol resin, acrylic resin, polyimide resin, or liquid crystal polymer. The first insulating layer 22 and the second insulating layer 23 may include filler. The first insulating layer 22 and the second insulating layer 23 may include inorganic insulating materials.

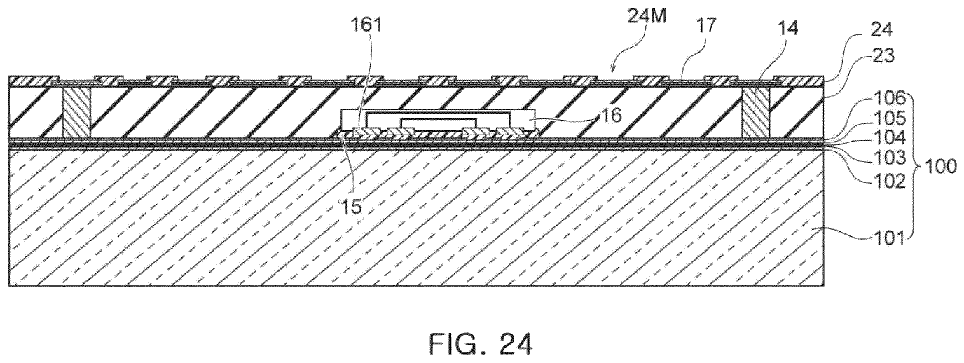

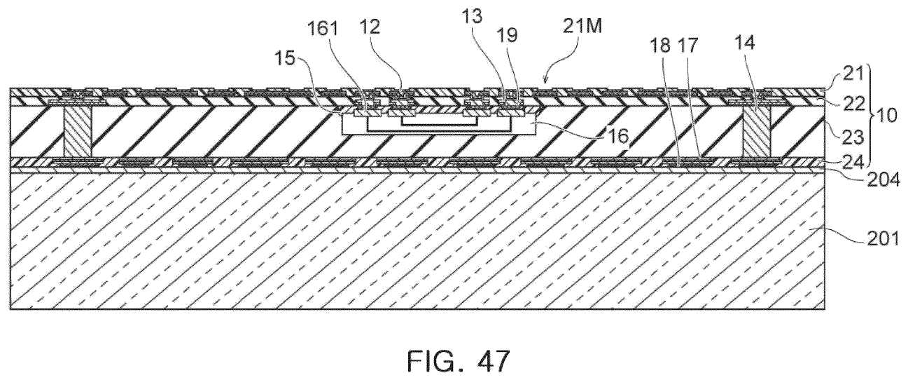

The first substrate electrode 11 is disposed on one end surface (e.g., X-Y plane) of the electronic component embedded substrate 10 in the Z-direction. The second substrate electrode 18 is disposed on the other end surface (e.g., X-Y plane) of the electronic component embedded substrate 10 in the Z-direction. The first substrate electrode 11 is provided, for example, in a through-hole (through-hole 21M of FIG. 47 described later) of the first solder resist layer 21. The second substrate electrode 18 is provided, for example, in a through-hole (through-hole 24M of FIG. 24 described later) of the second solder resist layer 24. The electronic component embedded substrate 10 has, for example, a plurality of first substrate electrodes 11 and a plurality of second substrate electrodes 18.

The first substrate electrodes 11 are provided, for example, at positions corresponding to the electrodes 311 of the semiconductor device 31 and the electrodes 321 of the semiconductor device 32, respectively. The second substrate electrodes 18 are provided, for example, at positions corresponding to the first electrodes 43 of the mounting substrate 40, respectively. The first substrate electrode 11 is electrically connected to the electrodes 311 and 321 via bumps 35 interposed therebetween. The second substrate electrode 18 is electrically connected to the first electrode 43 via bumps 45 interposed therebetween. The first substrate electrode 11 and the second substrate electrode 18 each include, for example, a conductive metal material such as gold, copper, nickel, or tin. The constituent materials of the first substrate electrode 11 and the constituent materials of the second substrate electrode 18 may be different. The first substrate electrode 11 and the second substrate electrode 18 include, for example, a plating film.

The relay conductive layer 12 is in contact with, for example, each of the plurality of first substrate electrodes 11. For example, the first substrate electrode 11 is provided in a selective area of the surface of the relay conductive layer 12. The relay conductive layer 12 is disposed in a desired (or alternatively, predetermined) pattern on, for example, the upper surface of the first insulating layer 22. For example, the surface and side surfaces of the relay conductive layer 12 are covered with the first solder resist layer 21. The relay conductive layer 12 includes, for example, a conductive metal material such as gold, platinum, palladium, silver, copper, aluminum, cobalt, titanium, chromium, nickel, tungsten, iron, tin, indium or zinc. The relay conductive layer 12 includes, for example, copper. The relay conductive layer 12 includes, for example, a plating film.

The first conductive layer 13 may electrically connect the relay conductive layer 12 and the electronic component 16 (e.g., the terminal electrode 161 of the electronic component 16 described below). The first conductive layer 13 includes, for example, a conductive metal material such as gold, platinum, palladium, silver, copper, aluminum, cobalt, titanium, chromium, nickel, tungsten, iron, tin, indium or zinc. The first conductive layer 13 is disposed on, for example, the second insulating layer 23 in a desired (or alternatively, predetermined) pattern. The first conductive layer 13 is provided, for example, in a plane (X-Y plane), at a position overlapping the electronic component 16. For example, the surface and side surface of the first conductive layer 13 are covered with the first insulating layer 22.

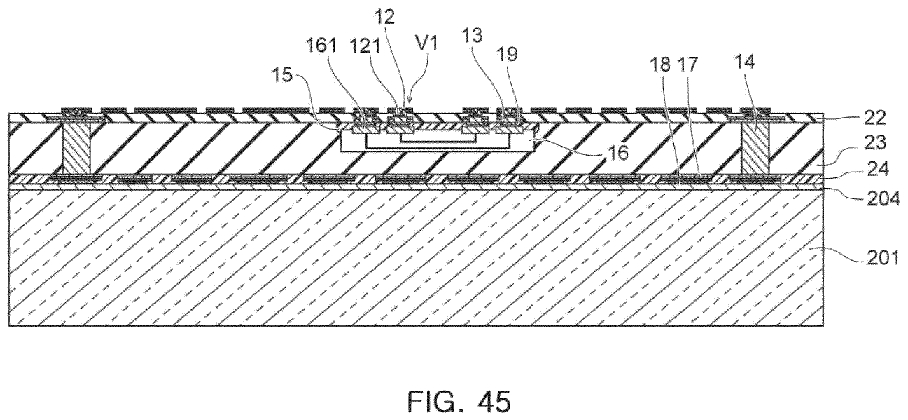

A via hole V1 reaching the surface of the first conductive layer 13 is provided in the first insulating layer 22. A relay conductive layer 12 is provided in the via hole V1. Accordingly, the first conductive layer 13 and the first substrate electrode 11 are electrically connected via the relay conductive layer 12. The relay conductive layer 12 may be connected to the first conductive layer 13 via a seed layer interposed therebetween (e.g., the seed layer 121 of FIG. 45 described below). The seed layer includes, for example, an adhesive film including titanium and a conductive film including copper.

The adhesive layer 15 is provided between the first insulating layer 22 and the electronic component 16. The adhesive layer 15 plays a role in bonding the electronic component 16 to the first insulating layer 22. The periphery of the adhesive layer 15 is covered with the second insulating layer 23.

The adhesive layer 15 includes, for example, an organic insulating material such as an epoxy resin, a phenol resin, an acrylic resin, a polyimide resin, or a liquid crystal polymer. The adhesive layer 15 may include a filler. The coefficient of linear expansion of the adhesive layer 15 may be lower than the coefficient of linear expansion of the second insulating layer 23. Accordingly, warpage of the electronic component embedded substrate 10 may be suppressed. The thermal conductivity of the adhesive layer 15 may be higher than the thermal conductivity of the second insulating layer 23. Accordingly, the heat dissipation of the electronic component embedded substrate 10 may be improved.

The electronic component 16 is embedded in the second insulating layer 23. The electronic component 16 has a desired (or alternatively, predetermined) function, such as an IC, a bridge, a condenser, a capacitor, an inductor, a coil, a thermistor, a resistor, or a fuse. The electronic component 16 is, for example, a semiconductor chip. Because the electronic component embedded substrate 10 has the electronic component 16, the electronic component embedded substrate 10 may function as an interposer connecting the semiconductor devices 31 and 32 and the mounting substrate 40. Accordingly, miniaturization and higher functionality of the electronic device may be implemented. The constituent material of the electronic component 16 is different from the constituent material of the first insulating layer 22. The elastic modulus of the electronic component 16 is different from the elastic modulus of the first insulating layer 22.

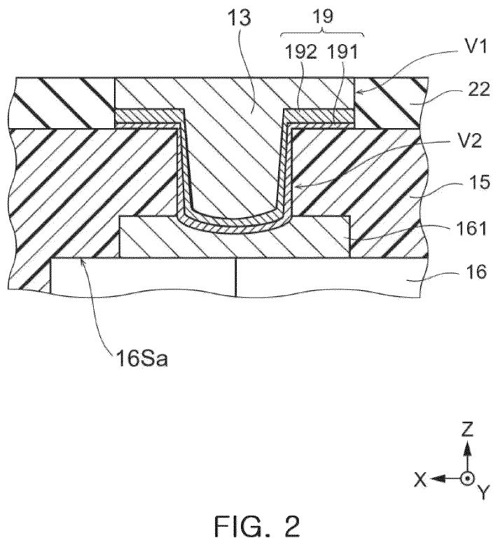

The electronic component 16 has, for example, a terminal surface (terminal surface 16Sa of FIG. 2 described later) facing the first insulating layer 22. The electronic component 16 has a terminal electrode 161 on the terminal surface. The electronic component 16 has, for example, a plurality of terminal electrodes 161.

A via hole V2 reaching the surface of the terminal electrode 161 is provided in the adhesive layer 15 provided between the terminal surface of the electronic component 16 and the first insulating layer 22. The via hole V2 accommodates a portion of the first conductive layer 13. Accordingly, the terminal electrode 161 and the first substrate electrode 11 are electrically connected via the relay conductive layer 12 and the first conductive layer 13 interposed therebetween. For example, the surface of the terminal electrode 161 corresponding to the via hole V2 (e.g., the surface of the terminal electrode 161 exposed by the via hole V2) is more recessed than other parts.

The second conductive layer 17 is, for example, in contact with each of a plurality of second substrate electrodes 18. For example, the second substrate electrodes 18 are provided in selective areas of the surface of the second conductive layer 17. The second conductive layer 17 is, for example, disposed in a desired (or alternatively, predetermined) pattern on the lower surface of the second insulating layer 23. For example, the surface and side surface of the second conductive layer 17 are covered with a second solder resist layer 24. The second conductive layer 17 includes a conductive metal material such as gold, platinum, palladium, silver, copper, aluminum, cobalt, titanium, chromium, nickel, tungsten, iron, tin, indium, or zinc. The second conductive layer 17 includes, for example, copper. The second conductive layer 17 includes, for example, a plating film.

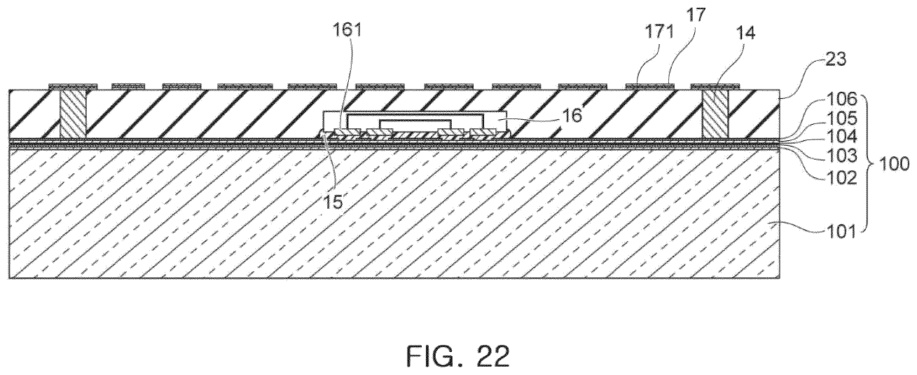

In the second insulating layer 23 in which the electronic component 16 is embedded, a pillar 14 is provided to connect the second conductive layer 17 and the first conductive layer 13. Accordingly, the first substrate electrode 11 and the second substrate electrode 18 are electrically connected via the relay conductive layer 12, the first conductive layer 13, and the second conductive layer 17. The second conductive layer 17 may be connected to the pillar 14 via a seed layer interposed therebetween (e.g., the seed layer 171 of FIG. 22 described below). The seed layer includes, for example, an adhesive film including titanium and a conductive film including copper.

### (Configuration of Via Hole V2)

FIG. 2 illustrates an enlarged view of the vicinity of the via hole V2 illustrated in FIG. 1. The first conductive layer 13 in the via hole V2, which is formed in the adhesive layer 15, is electrically connected to the terminal electrode 161 of the electronic component 16. The terminal electrode 161 is provided on the terminal surface 16Sa of the electronic component 16. The terminal surface 16Sa faces the first insulating layer 22 with the adhesive layer 15 interposed therebetween. At least a part of the first conductive layer 13 faces the terminal surface 16Sa with the adhesive layer 15 interposed therebetween. In this case, the terminal surface 16Sa corresponds to one specific example of the first terminal surface of the present inventive concepts, and the terminal electrode 161 corresponds to one specific example of the first electrode of the present inventive concepts.

The via hole V2 has, for example, a circular plane (X-Y plane) shape. The hole diameter (diameter) of the via hole V2 is, for example, about 5 μm to about 50 μm. The hole diameter of the via hole V2 is, for example, almost constant in the thickness direction (Z-direction) of the adhesive layer 15. That is, the hole diameter of the via hole V2 is substantially the same in the thickness direction of the adhesive layer 15. Being substantially the same means being the same within the range of errors occurring under all conditions such as manufacturing conditions. A bottom boundary of the via hole V2, through which a portion of an upper surface of the terminal electrode 161 is exposed, has, for example, a curved surface. The via hole V2 with the curved surface is formed, for example, by using a dry etching method.

In the via hole V2, for example, a seed layer 19 is provided together with the first conductive layer 13. The seed layer 19 is provided, for example, from the upper surface of the adhesive layer 15 to the entire wall surface of the via hole V2. The first conductive layer 13 is electrically connected to the terminal electrode 161 via the seed layer 19 interposed therebetween.

In the present example embodiment, the seed layer 19 includes an adhesive film 191 and a conductive film 192. The adhesive film 191 is provided between the wall surface of the via hole V2 and the conductive film 192. The conductive film 192 is provided between the adhesive film 191 and the first conductive layer 13. For example, the adhesive film 191, the conductive film 192, and the first conductive layer 13 are laminated in order from the wall surface side of the via hole V2. Although the details will be described later, in the present example embodiment, because the seed layer 19 has an adhesive film 191 between the conductive film 192 and the wall surface of the via hole V2, the seed layer 19 easily adheres to the wall surface of the via hole V2.

The adhesion between the adhesive film 191 and the adhesive layer 15 is higher than the adhesion between the conductive film 192 and the adhesive layer 15. Accordingly, the seed layer 19 easily adheres to the wall surface of the via hole V2. The adhesive film 191 is in contact with the wall surface of the via hole V2, for example. In other words, the adhesive film 191 defines a boundary of the via hole V2.

The adhesive film 191 and the conductive film 192 each contain, for example, a conductive metal material such as gold, platinum, palladium, silver, copper, aluminum, cobalt, titanium, chromium, nickel, tungsten, iron, tin, indium, or zinc. For example, the adhesive film 191 and the conductive film 192 contain at least one of copper, aluminum, titanium, or chromium. For example, the adhesive film 191 contains titanium, and the conductive film 192 contains copper. Accordingly, the adhesion of the seed layer 19 may be maintained, and also the thickness may be suppressed. The wall surface of the via hole V2 is covered with, for example, the seed layer 19.

The thickness of each of the adhesive film 191 and the conductive film 192 varies, for example, across the thickness direction of the adhesive layer 15. The thickness of each of the adhesive film 191 and the conductive film 192 in the via hole V2 gradually increases, for example, towards the electronic component 16 side from the first insulating layer 22 side. That is, the thickness of each of the adhesive film 191 and the conductive film 192 increases towards the terminal electrode 161. The thickness of each of the adhesive film 191 and the conductive film 192 is, for example, the largest at a portion in contact with the terminal electrode 161. The thickness of each of the adhesive film 191 and the conductive film 192 of the thickest part are, for example, about 10 nm to about 50 nm, and the thickness of each of the adhesive film 191 and the conductive film 192 of the thinnest part is, for example, 0.5 to 0.99 times the thickness of the thickest part. The adhesive film 191 and the conductive film 192 may be formed, for example, using a sputtering method. For example, the adhesive film 191 and the conductive film 192 include a sputtered film. At least one of the adhesive film 191 or the conductive film 192 may include a sputtered film. Meanwhile, the thickness of the adhesive film 191 and the conductive film 192 may generally increase towards the terminal electrode 161, but may have a portion locally decreasing.

### (Method of Manufacturing Electronic Device)

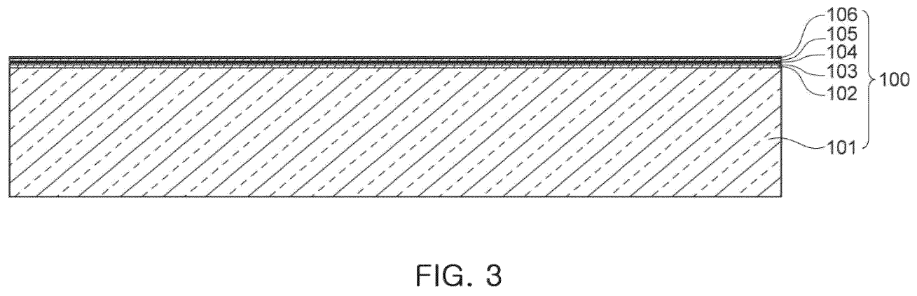

Next, an example of a method of manufacturing electronic devices will be described using FIGS. 3 to 53.

First, a support substrate 100 is prepared (FIG. 3). The support substrate 100 includes, for example, a support 101, a first adhesive layer 102, a second adhesive layer 103, a peeling layer 104, a first seed layer 105, and a second seed layer 106. The support 101 is composed of a plate-shaped member including, for example, at least one of glass, silicon (Si), Stainless Used Steel (SUS), ferrite, alumina, or prepreg. In terms of thermal expansion coefficient and surface smoothness, the support 101 may include glass. In the support substrate 100, a first adhesion layer 102, a second adhesion layer 103, a peeling layer 104, a first seed layer 105, and a second seed layer 106 are sequentially laminated on a support 101.

The first adhesion layer 102, the second adhesion layer 103, the first seed layer 105, and the second seed layer 106 contain a conductive metal such as gold, platinum, palladium, silver, copper, aluminum, cobalt, titanium, chromium, nickel, tungsten, iron, tin, indium, or zinc. In terms of adhesion between layers, the first adhesion layer 102 and the first seed layer 105 may contain titanium. In terms of conductivity and cost, the second adhesion layer 103 and the second seed layer 106 may contain copper. The peeling layer 104 includes, for example, an inorganic material and copper. The first adhesion layer 102, the second adhesion layer 103, the first seed layer 105, and the second seed layer 106 are formed, for example, by using a metal foil press method, a plating method, or a sputtering method. The support substrate 100 is configured, for example, by High Resolution De-bondable Panel (HRDP™).

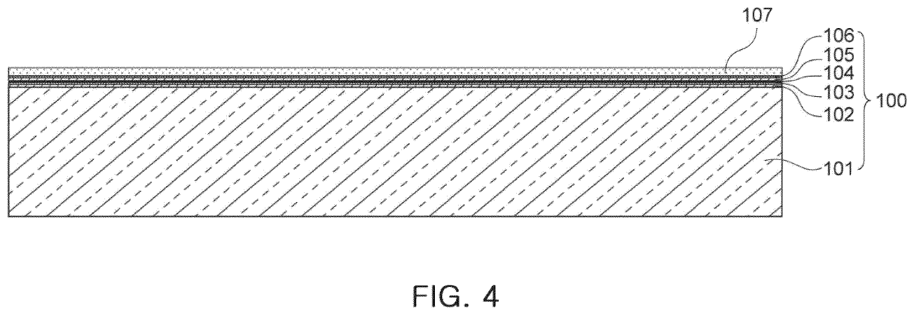

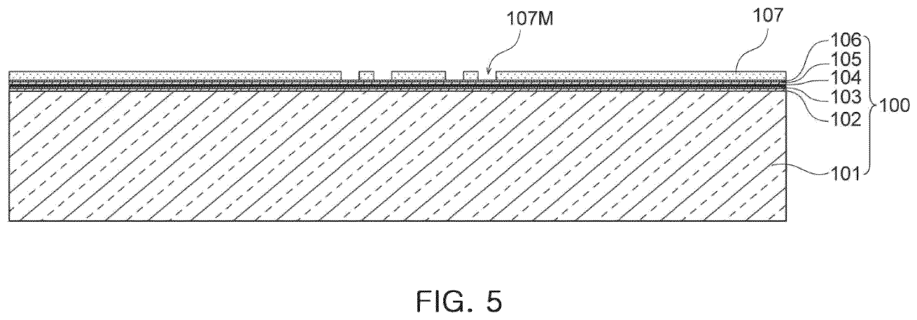

Next, a resist film 107 is formed on the second seed layer 106 (FIG. 4). Subsequently, a through-hole 107M is formed in the resist film 107 (FIG. 5). The through-hole 107M is formed, for example, by using a photolithography method.

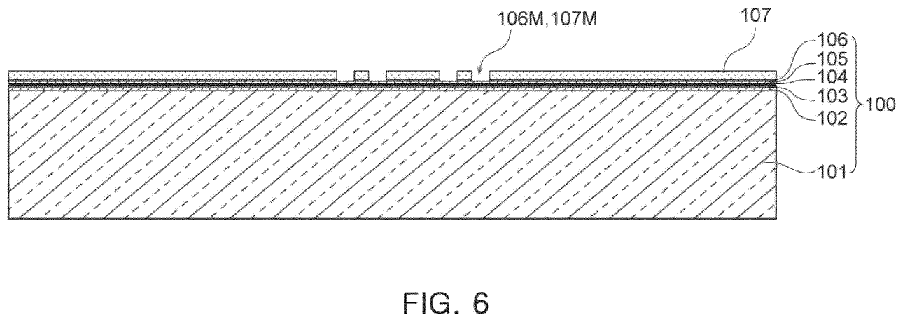

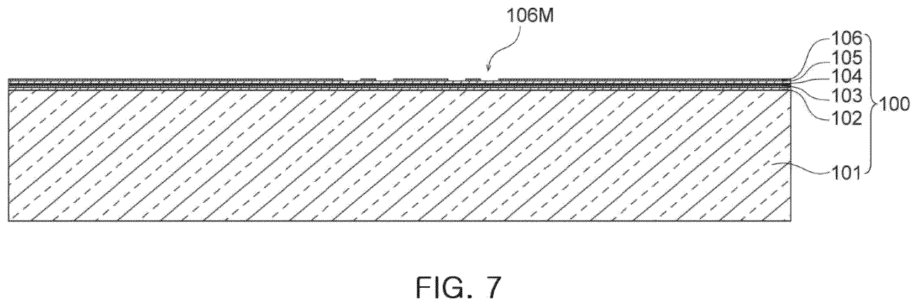

After forming a through-hole 107M in the resist film 107, a through-hole 106M of the second seed layer 106 is formed using this through-hole 107M (FIG. 6). Subsequently, the resist film 107 is removed (FIG. 7). For example, a plurality of through-holes 106M are formed.

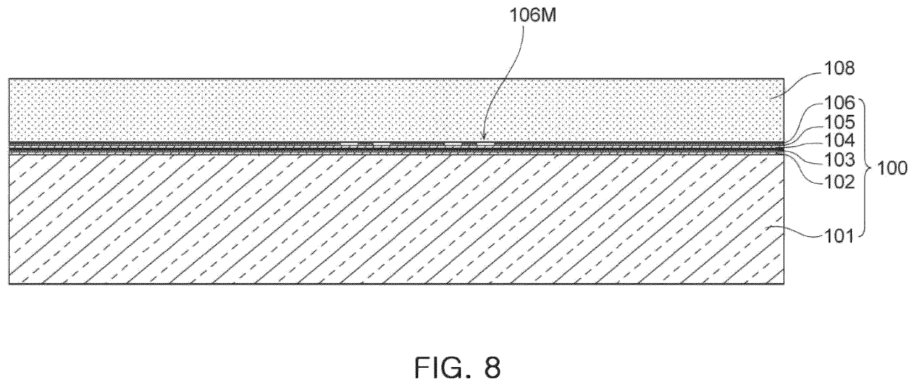

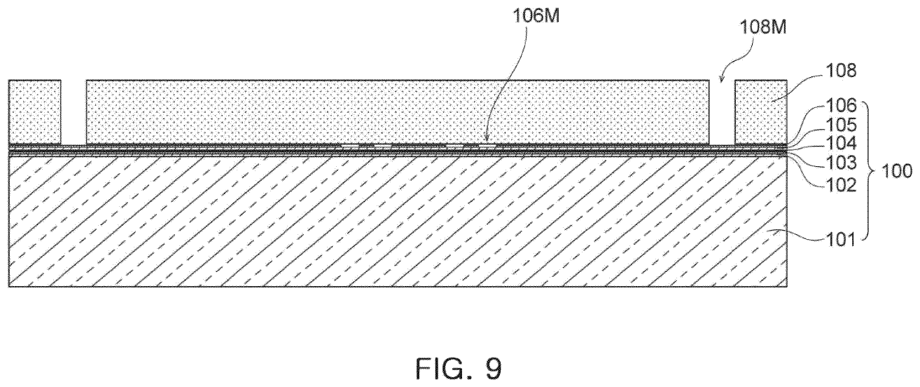

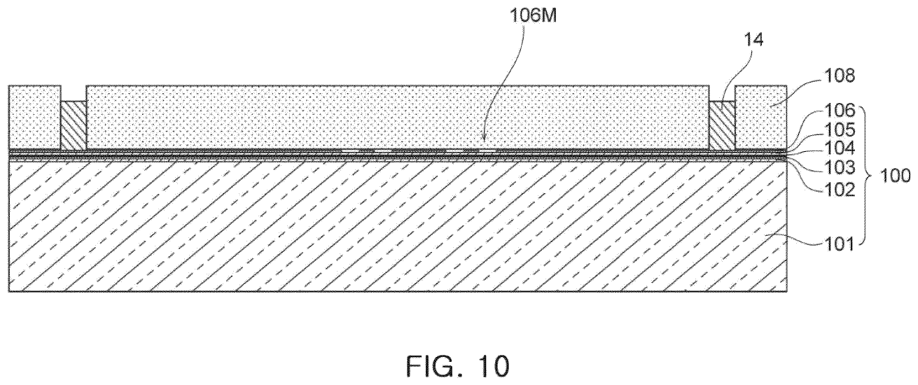

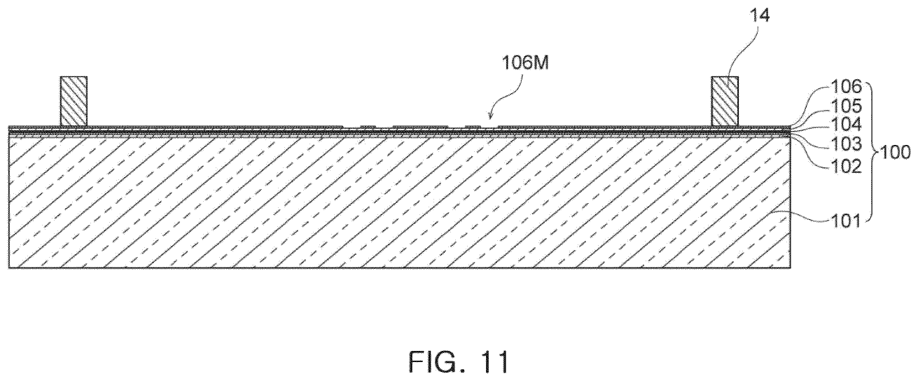

After removing the resist film 107, a resist film 108 is formed on the second seed layer 106 (FIG. 8). Subsequently, a through-hole 108M is formed in the resist film 108 (FIG. 9). Subsequently, a pillar 14 is formed in the through-hole 108M (FIG. 10), and the resist film 108 is removed (FIG. 11).

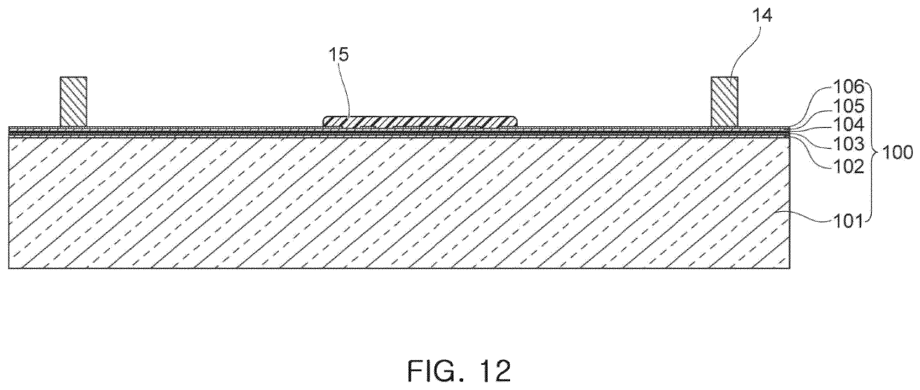

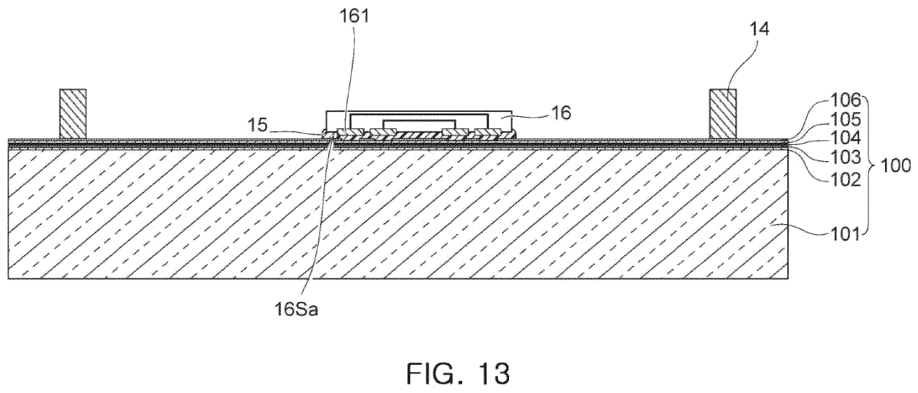

After removing the resist film 108, an electronic component 16 is mounted in a portion where a through-hole 106M is formed on the second seed layer 106 by interposing an adhesive layer 15. For example, after providing an adhesive layer 15 on the second seed layer 106 (FIG. 12), an electronic component 16 is mounted on the support substrate 100 so that the main surface of the support substrate 100 and the terminal surface 16Sa face each other (FIG. 13). For example, the electronic component 16 is mounted on the support substrate 100 in a face-down manner. Accordingly, the alignment precision may be improved. The adhesive layer 15 may be in any shape, such as a paste shape or a film shape. For example, the adhesive layer 15 may have a paste shape.

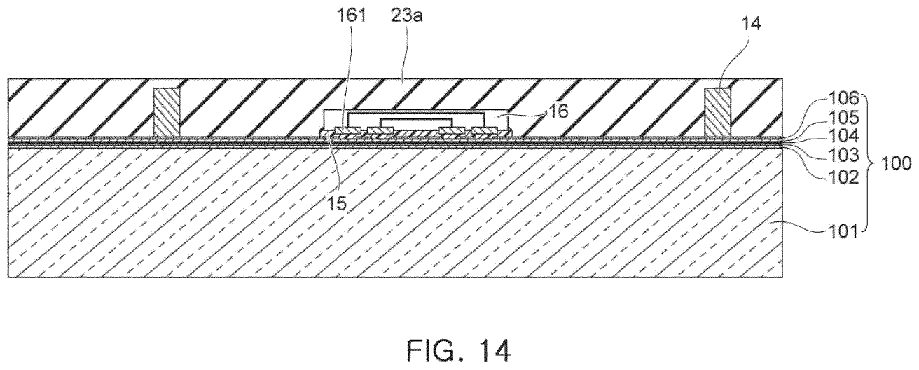

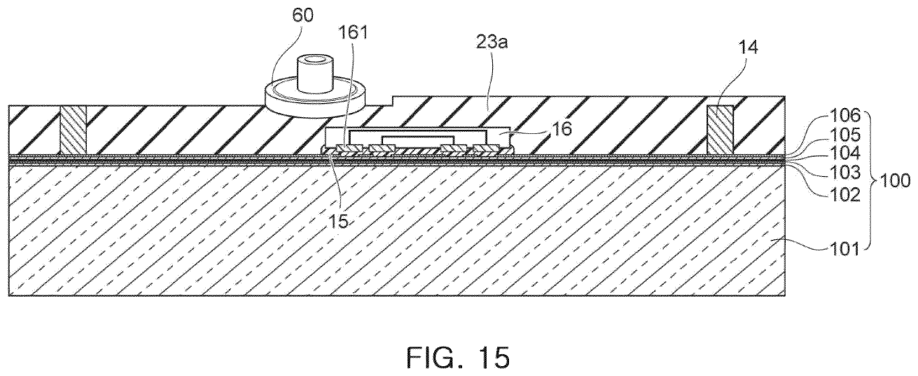

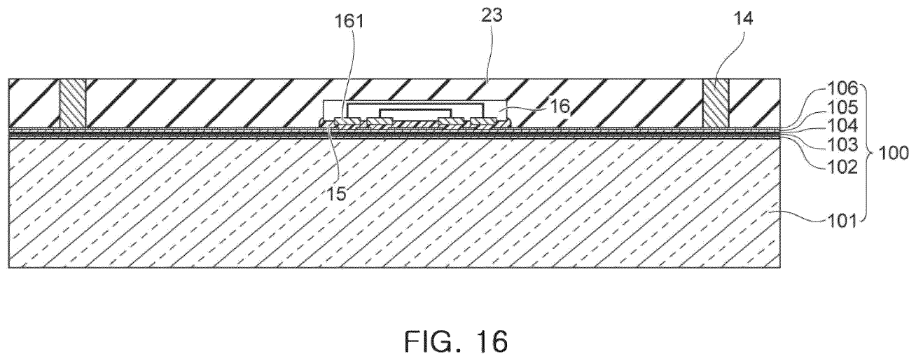

After mounting the electronic component 16 on the support substrate 100, a second insulating layer 23 is formed on the support substrate 100 (FIG. 14, FIG. 15 and FIG. 16). The second insulating layer 23 is formed, for example, as follows.

First, an organic insulating material 23a is formed on the support substrate 100 using a film lamination method or a spin coating method (FIG. 14). By forming the second insulating layer 23 using the film lamination method, the organic insulating material 23a with relatively high surface flatness may be formed. Next, the organic insulating material 23a is flattened (FIG. 15). For example, the organic insulating material 23a is flattened using a Chemical Mechanical Polishing (CMP) method. In the CMP method, for example, the organic insulating material 23a is flattened using a polishing head 60. Meanwhile, in FIG. 15, the perspective configuration of the polishing head 60 is illustrated for easy viewing of the drawing. By flattening the organic insulating material 23a until one end of the pillar 14 is exposed (FIG. 15), the second insulating layer 23 is formed (FIG. 16).

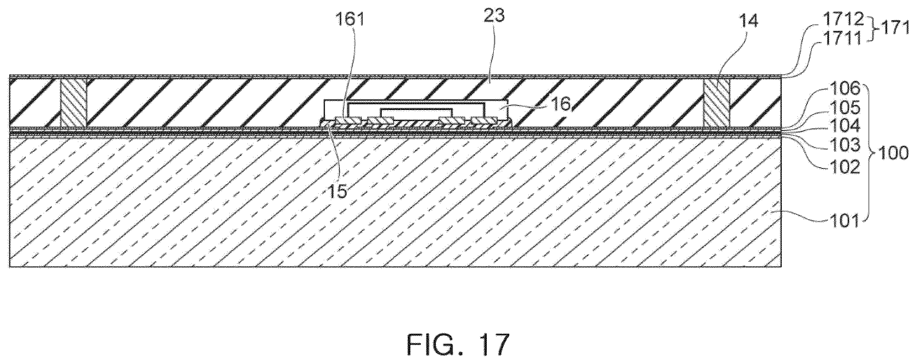

After forming the second insulating layer 23, the second conductive layer 17 is formed on the second insulating layer 23 (FIGS. 17 to 20). The second conductive layer 17 is formed, for example, using a semi-additive process as follows.

First, a seed layer 171 is formed on the second insulating layer 23 (FIG. 17). The seed layer 171 includes, for example, an adhesive film 1711 and a conductive film 1712. For example, after forming the adhesive film 1711 on the second insulating layer 23, a conductive film 1712 is formed on the adhesive film 1711. The adhesive film 1711 and the conductive film 1712 include, for example, a conductive metal material such as titanium, aluminum, and/or copper. For example, the adhesive film 1711 may contain titanium, and the conductive film 1712 may contain copper. The seed layer 171 is formed using, for example, an electroless plating method, a sputtering method, a Chemical Vapor Deposition (CVD) method, or an Atomic Layer Deposition (ALD) method. For example, the seed layer 171 may be formed using a sputtering method.

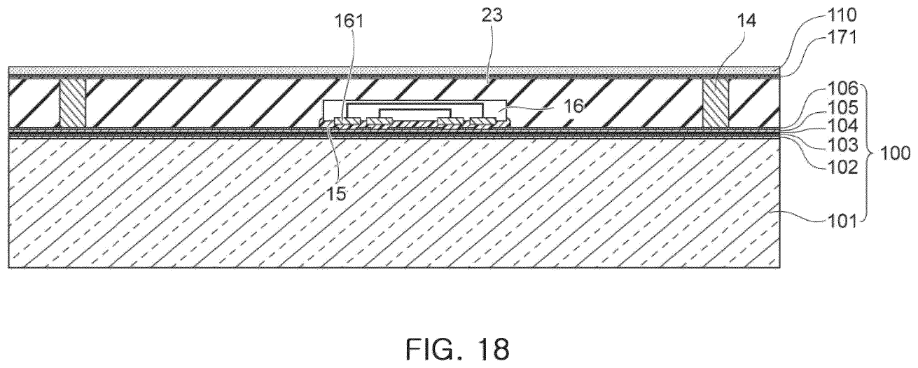

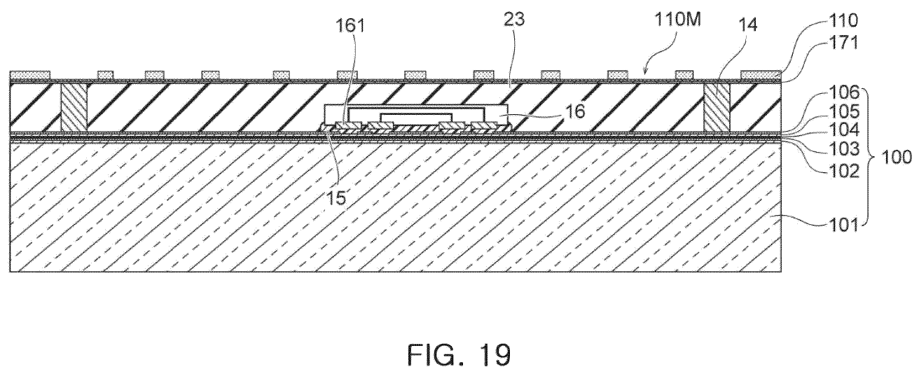

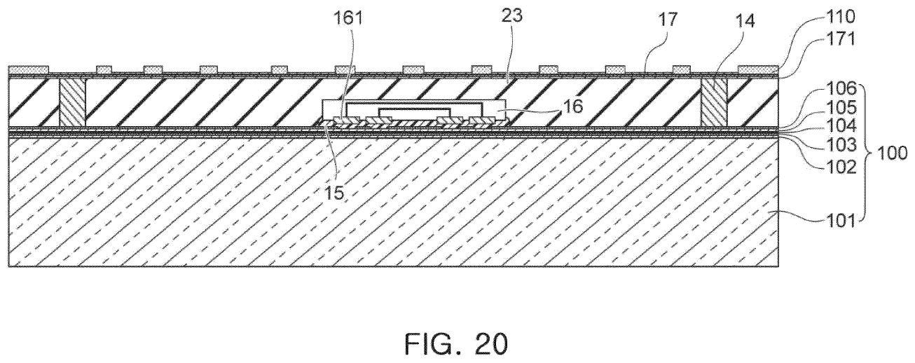

After the seed layer 171 is formed, a resist film 110 is formed on the seed layer 171 (FIG. 18). Subsequently, a through-hole 110M is formed in the resist film 110 (FIG. 19). Thereafter, a conductive metal material is plated and grown in the through-hole 110M of the resist film 110. Accordingly, a second conductive layer 17 is formed in the through-hole 110M of the resist film 110 (FIG. 20).

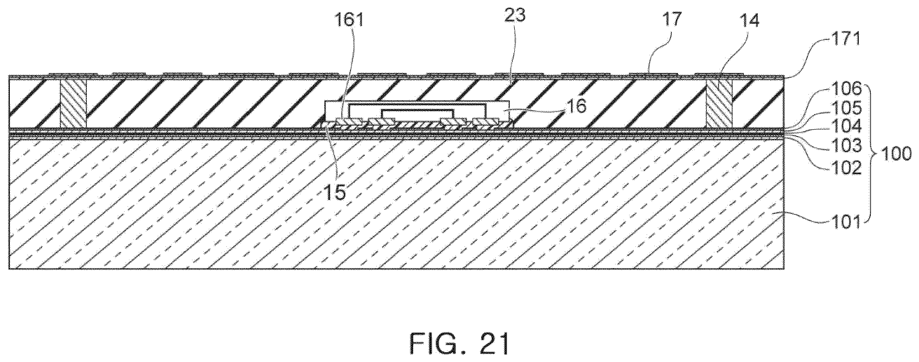

After forming the second conductive layer 17, the resist film 110 is removed (FIG. 21). Subsequently, the seed layer 171 exposed by the second conductive layer 17 is removed, for example, using an etching method (FIG. 22). Accordingly, the seed layer 171 (e.g., a seed layer formed by removing a portion of the seed layer 171 that is exposed by the second conductive layer 17) and the second conductive layer 17 are formed.

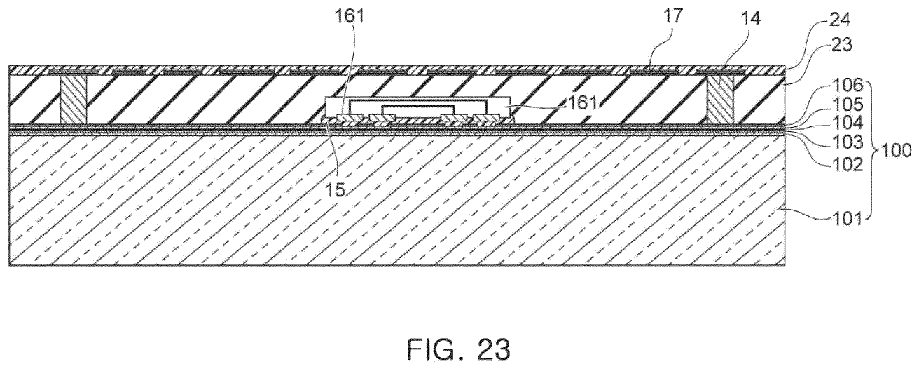

After forming the second conductive layer 17, the second solder resist layer 24 is formed (FIG. 23). For example, the second solder resist layer 24 is formed on the second insulating layer 23 to cover the second conductive layer 17. Subsequently, a through-hole 24M is formed in the second solder resist layer 24 (FIG. 24). The through-hole 24M of the second solder resist layer 24 is formed at a position corresponding to the second conductive layer 17. The second solder resist layer 24 is formed, for example, using a photolithography method or a printing method.

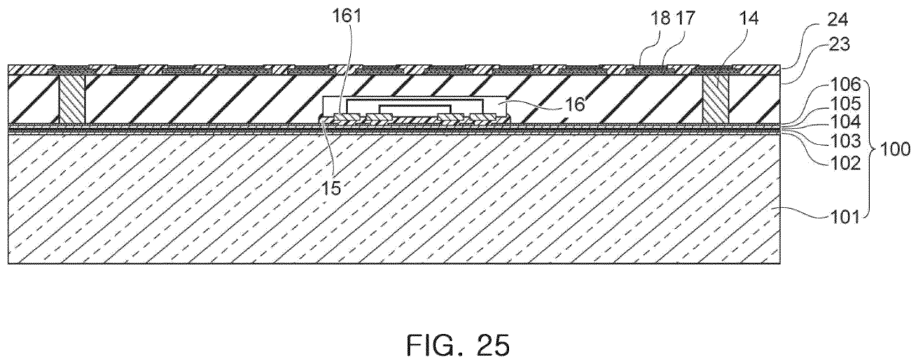

After forming a through-hole 24M in the second solder resist layer 24, a second substrate electrode 18 is formed in the through-hole 24M (FIG. 25). The second substrate electrode 18 is formed, for example, using an electroless plating method or an electrolytic plating method.

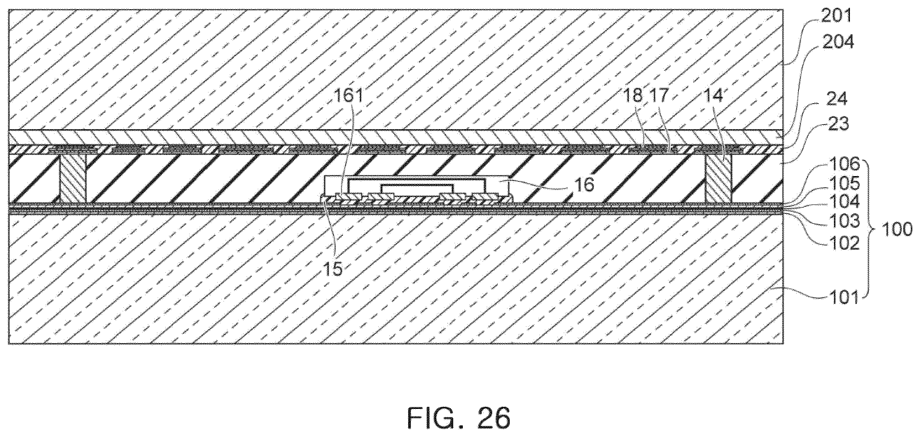

After forming the second substrate electrode 18, a support 201 is attached to the second solder resist layer 24 with a release layer 204 interposed therebetween (FIG. 26). The support 201 is, for example, a plate-shaped member and is composed of the same material as the support 101. The support 201 includes, for example, glass. The release layer 204 includes, for example, epoxy resin or acrylic resin. A film including a metal material such as titanium, copper or nickel may be provided between the second solder resist layer 24 and the release layer 204.

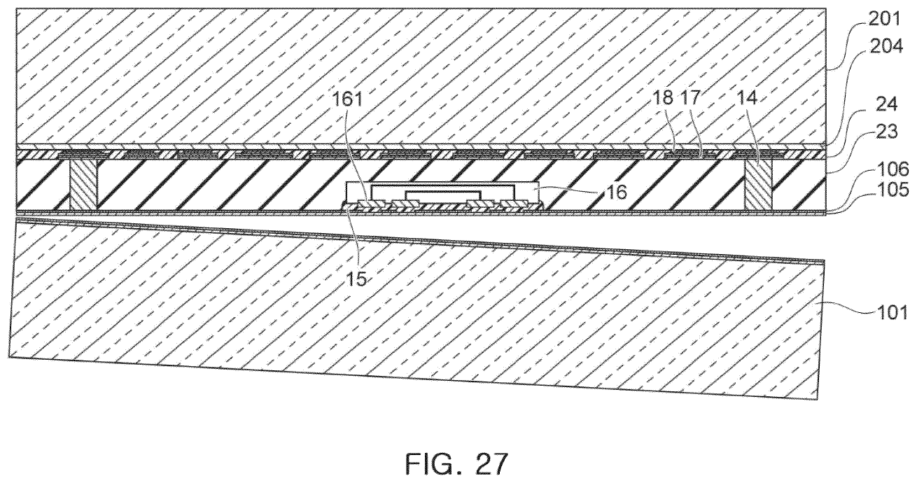

After attaching the support 201 to the second solder resist layer 24, the support 101 is removed (FIG. 27). For example, by irradiating the peeling layer 104 with a laser or ultraviolet (UV), the peeling layer 104 and the support 101 are peeled from the first seed layer 105. For example, the support 101 may be peeled by reducing the adhesion between the peeling layer 104 and the first seed layer 105 using a chemical reaction by a chemical agent. In some example embodiments, the support 101 may be peeled by applying physical force to the support 101.

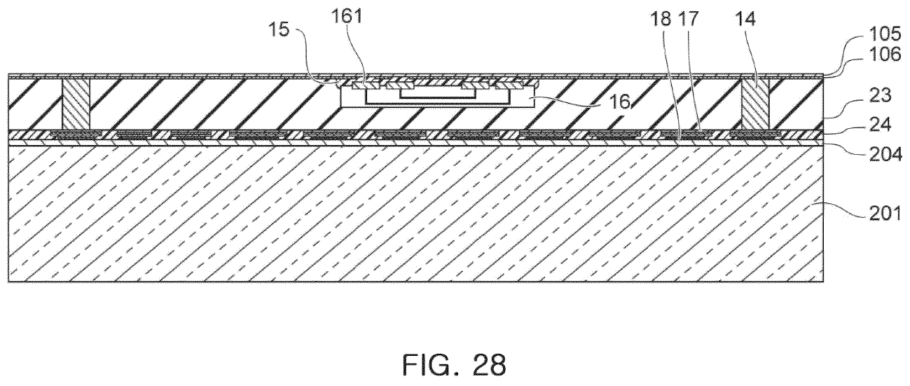

After removing the support 101, the support 201 is inverted (FIG. 28). Accordingly, the first seed layer 105 and the second seed layer 106 are disposed on the upper surface side of the support 201.

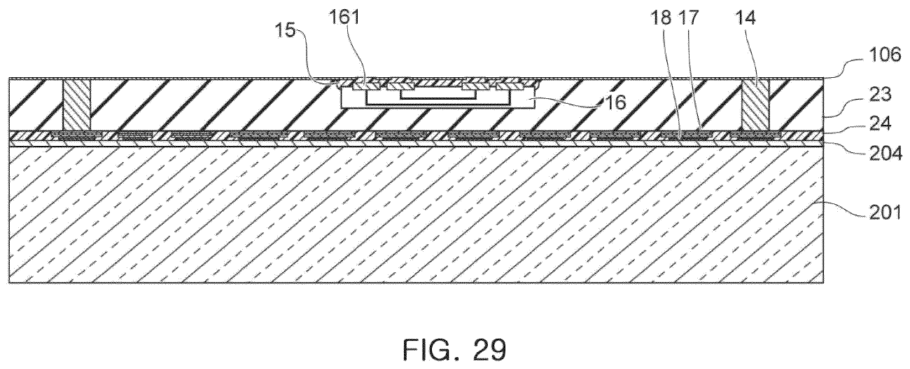

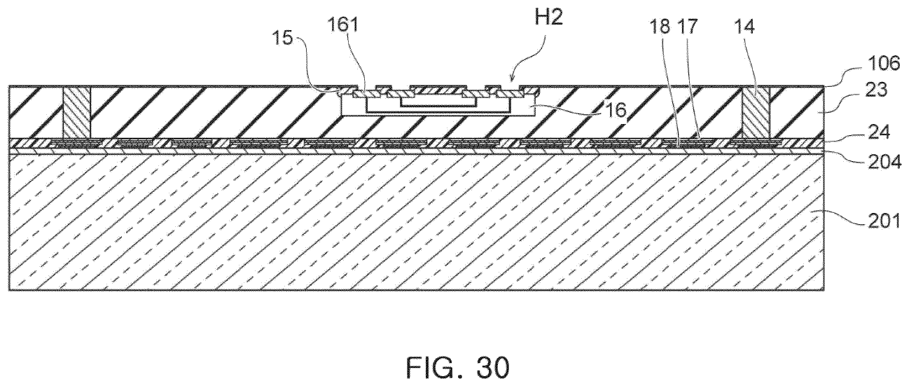

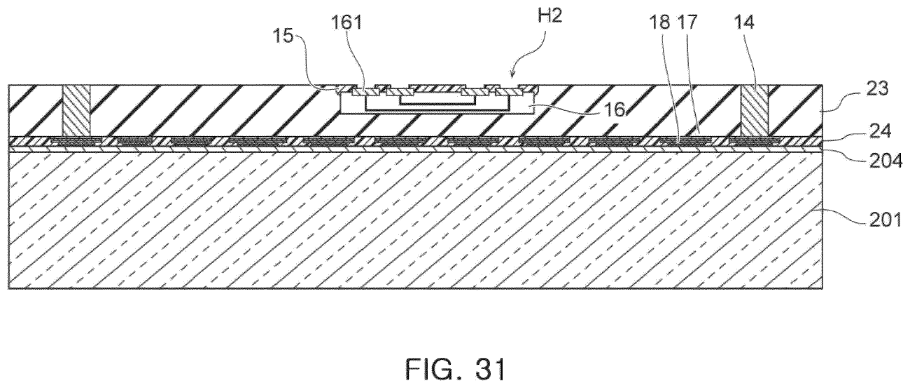

Next, the first seed layer 105 is removed (FIG. 29). The first seed layer 105 is removed, for example, by a chemical etching method using a chemical agent. After the first seed layer 105 is removed, an opening H2 exposing the terminal electrode 161 is formed in the adhesive layer 15 (FIG. 30). In the opening H2, a seed layer 19 and a first conductive layer 13 are formed, thereby forming a via hole V2 filled with the seed layer 19 and the first conductive layer 13. The opening H2 is formed, for example, by using a through-hole 106M (FIG. 6) of the second seed layer 106 and a dry etching method. After forming the opening H2, the second seed layer 106 is removed (FIG. 31). For example, at this time, the surface of the exposed terminal electrode 161 is cut off (e.g., partially removed).

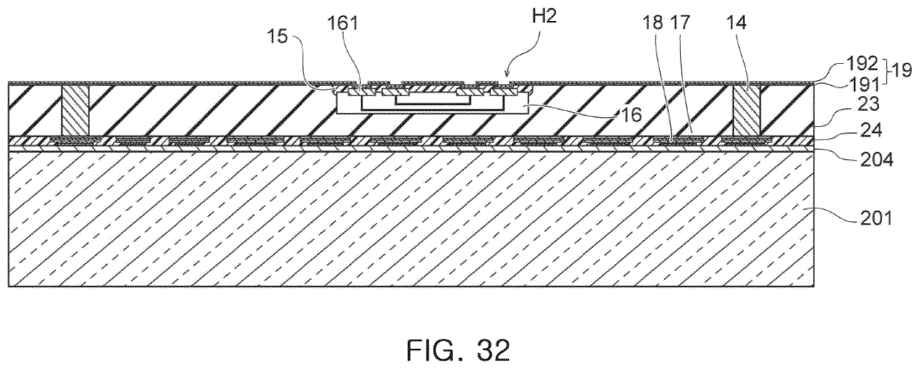

Next, the seed layer 19 is formed on the second insulating layer 23 and within the opening H2 (FIG. 32). For example, by forming an adhesive film 191 and a conductive film 192 in order on the second insulating layer 23 and within the opening H2, the seed layer 19 is formed. The seed layer 19 is formed using, for example, an electroless plating method, a sputtering method, a CVD method, or an ALD method. For example, the seed layer 19 may be formed using a sputtering method.

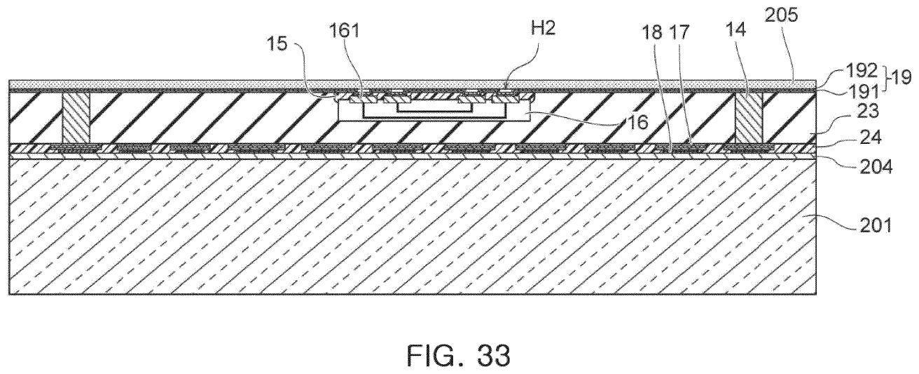

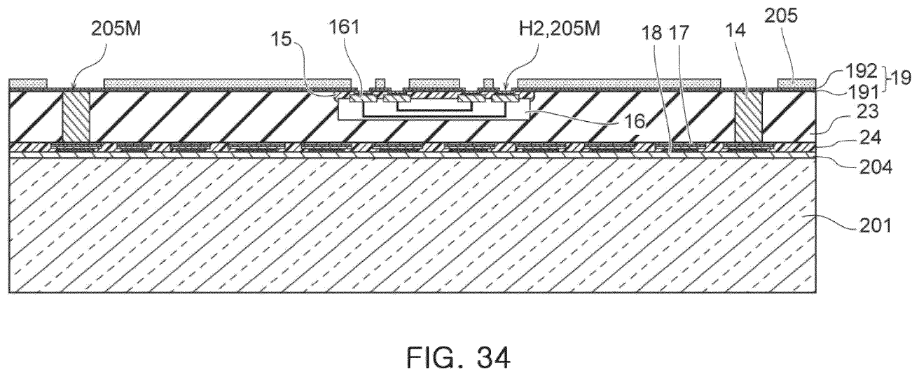

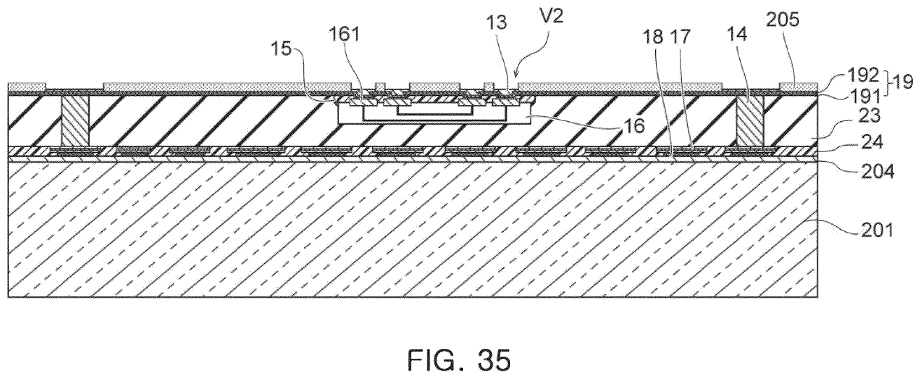

After forming the seed layer 19, a resist film 205 is formed on the seed layer 19 (FIG. 33). Next, a through-hole 205M is formed in the resist film 205 (FIG. 34). The through-hole 205M is formed in a region overlapping at least the opening H2 and the pillar 14 in a plane (X-Y plane). Then, a conductive metal material is plated and grown in the through-hole 205M of the resist film 205. Accordingly, a first conductive layer 13 is formed in the through-hole 205M of the resist film 205 (FIG. 35). For example, a via hole V2 having a seed layer 19 and a first conductive layer 13 therein is formed.

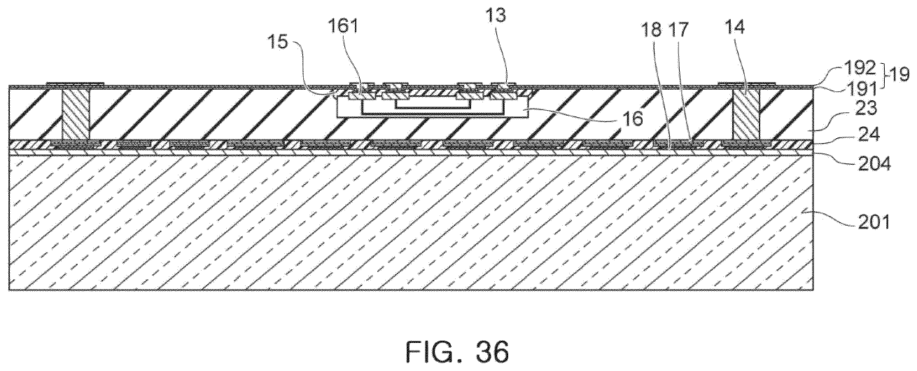

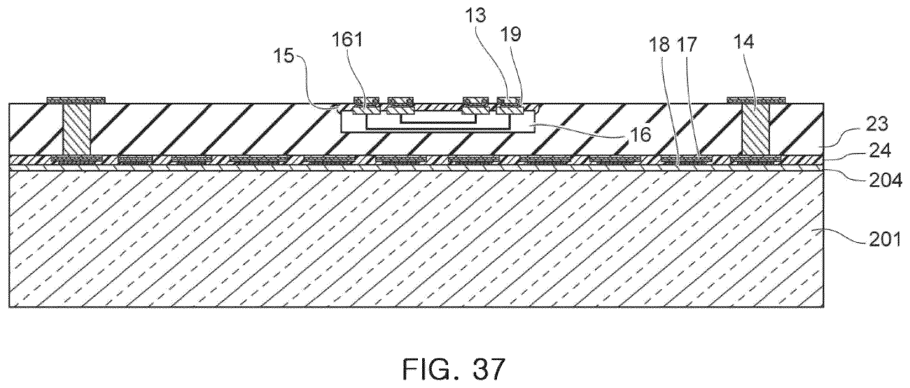

After forming the first conductive layer 13, the resist film 205 is removed (FIG. 36). Subsequently, the seed layer 19 exposed from or by the first conductive layer 13 is removed, for example, using an etching method (FIG. 37).

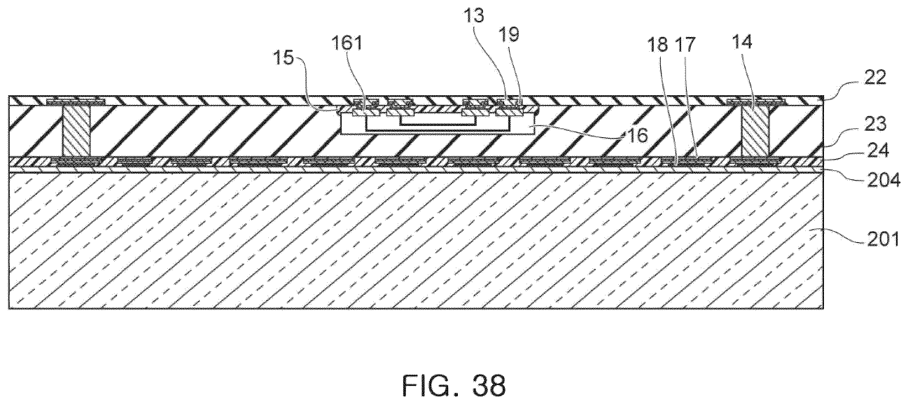

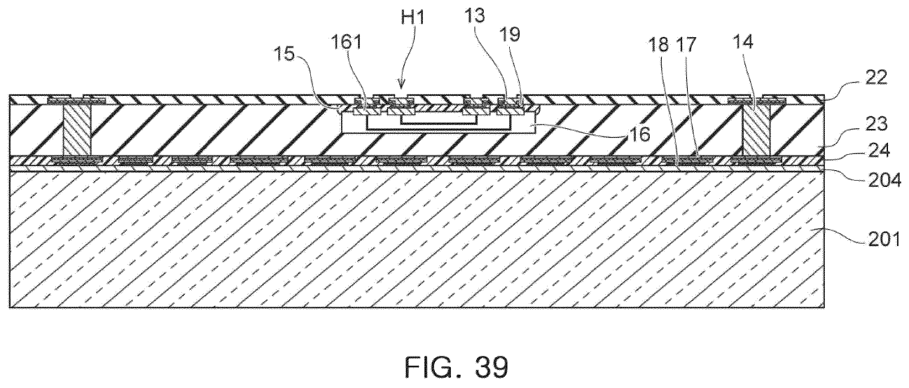

Next, the first insulating layer 22 is formed by covering the first conductive layer 13 on the second insulating layer 23 (FIG. 38). Subsequently, an opening H1 exposing the first conductive layer 13 is formed in the first insulating layer 22 (FIG. 39). The opening H1 is formed, for example, using a dry etching method. The opening H1 may correspond to a via hole V1 to be filled with a seed layer 121 and a relay conductive layer 12.

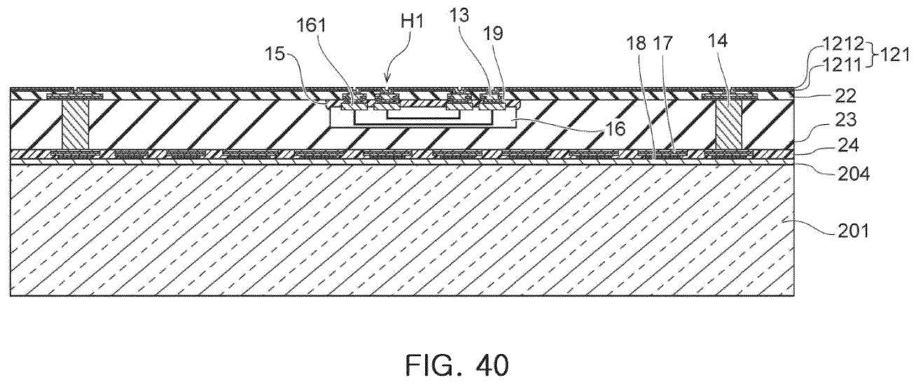

Next, the seed layer 121 is formed on the first insulating layer 22 and within the opening H1 (FIG. 40). For example, by forming an adhesive film 1211 and a conductive film 1212 in order on the first insulating layer 22 and within the opening H1, the seed layer 121 is formed. The seed layer 121 is formed, for example, using an electroless plating method, a sputtering method, a CVD method, or an ALD method. For example, the seed layer 121 may be formed using a sputtering method.

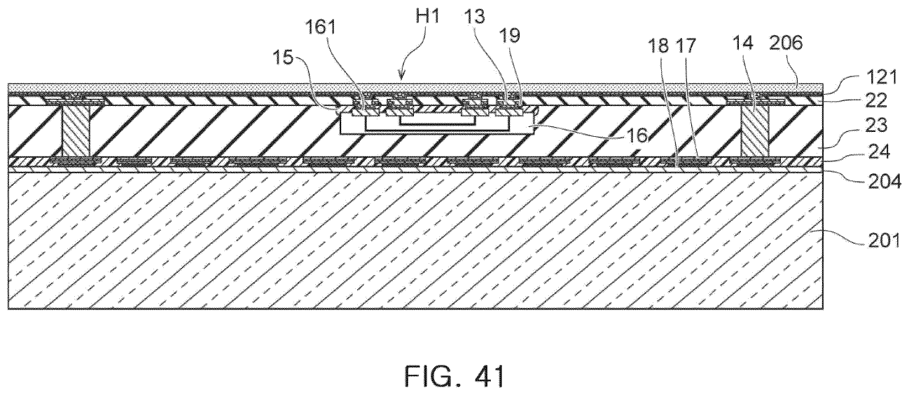

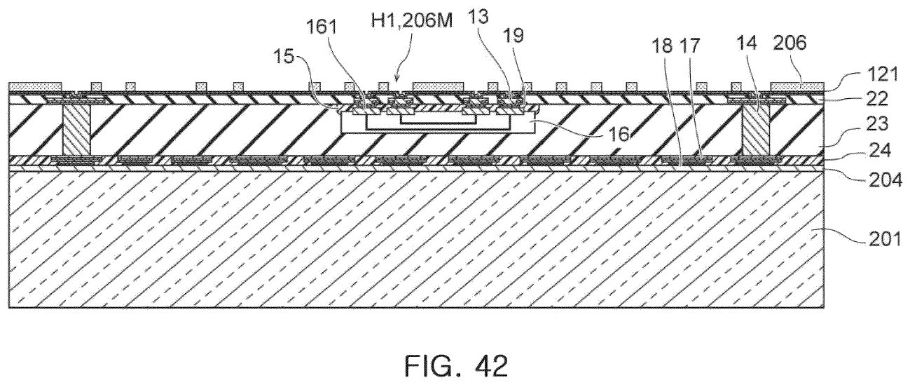

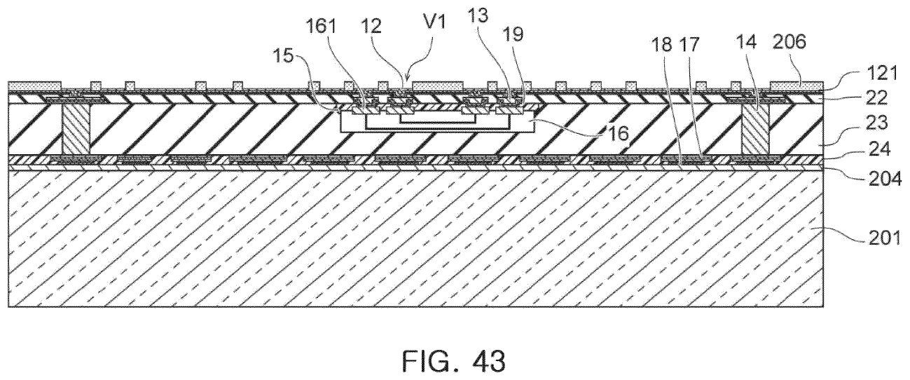

After forming the seed layer 121, a resist film 206 is formed on the seed layer 121 (FIG. 41). Next, a through-hole 206M is formed in the resist film 206 (FIG. 42). The through-hole 206M is formed in a region overlapping at least the opening H1 and the pillar 14 in a plane (X-Y plane). Thereafter, a conductive metal material is plated and grown in the through-hole 206M of the resist film 206. Accordingly, a relay conductive layer 12 is formed in the through-hole 206M of the resist film 206 (FIG. 43). For example, a via hole V1 having a seed layer 121 and a relay conductive layer 12 therein is formed.

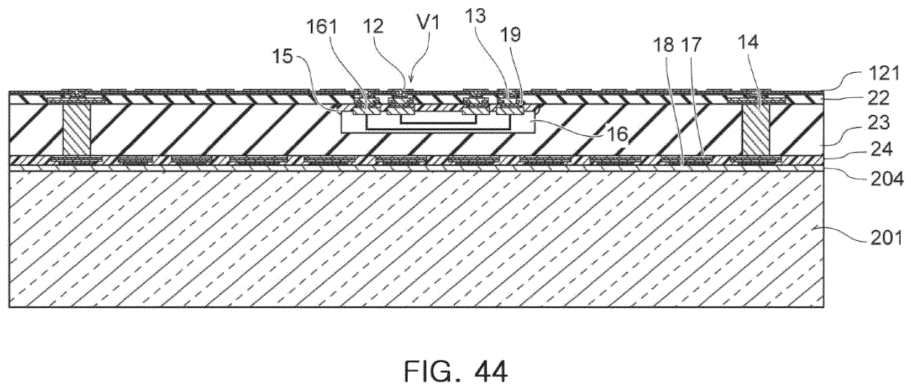

After forming the relay conductive layer 12, the resist film 206 is removed (FIG. 44). Subsequently, the seed layer 121 exposed from the relay conductive layer 12 is removed, for example, using an etching method (FIG. 45).

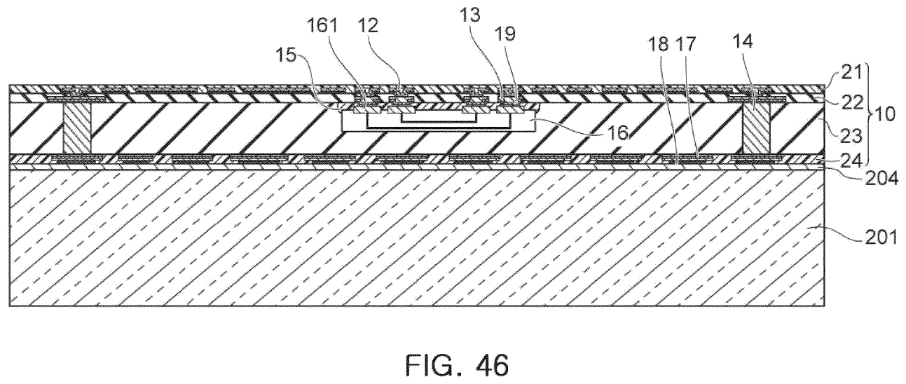

Next, a first solder resist layer 21 is formed (FIG. 46). For example, a first solder resist layer 21 is formed on a first insulating layer 22 to cover a relay conductive layer 12. Subsequently, a through-hole 21M is formed in the first solder resist layer 21 (FIG. 47). The through-hole 21M of the first solder resist layer 21 is formed at a position corresponding to the relay conductive layer 12. The first solder resist layer 21 is formed, for example, using a photolithography method or a printing method.

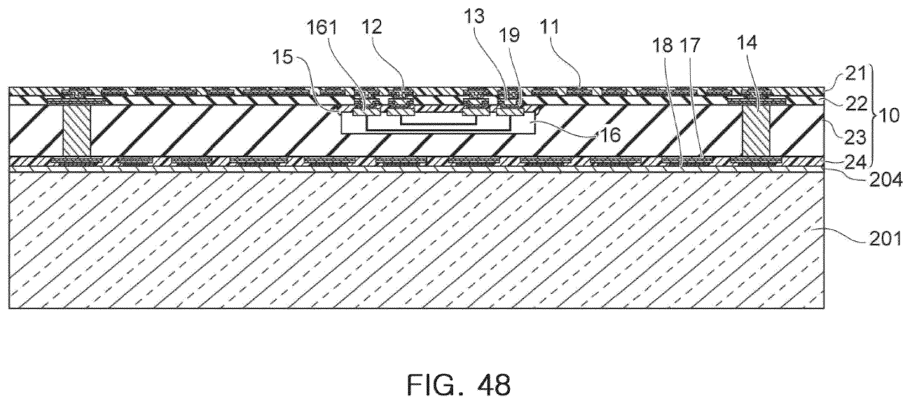

After forming the through-hole 21M in the first solder resist layer 21, a first substrate electrode 11 is formed in the through-hole 21M (FIG. 48). The first substrate electrode 11 is formed, for example, using an electroless plating method or an electrolytic plating method. Accordingly, an electronic component embedded substrate 10 is formed.

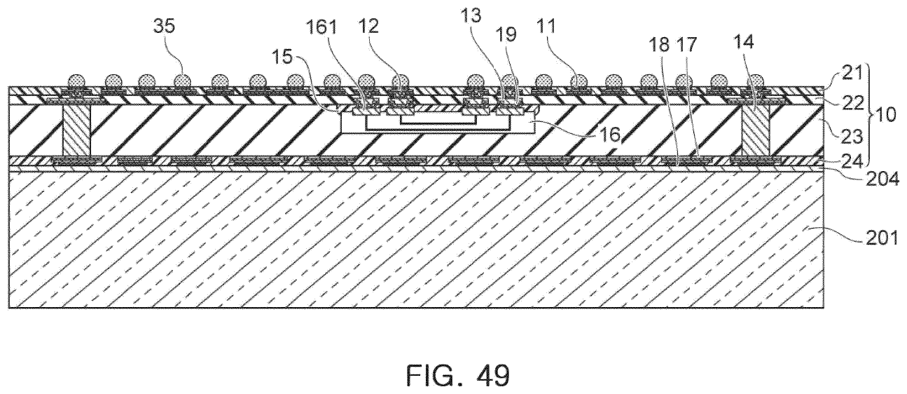

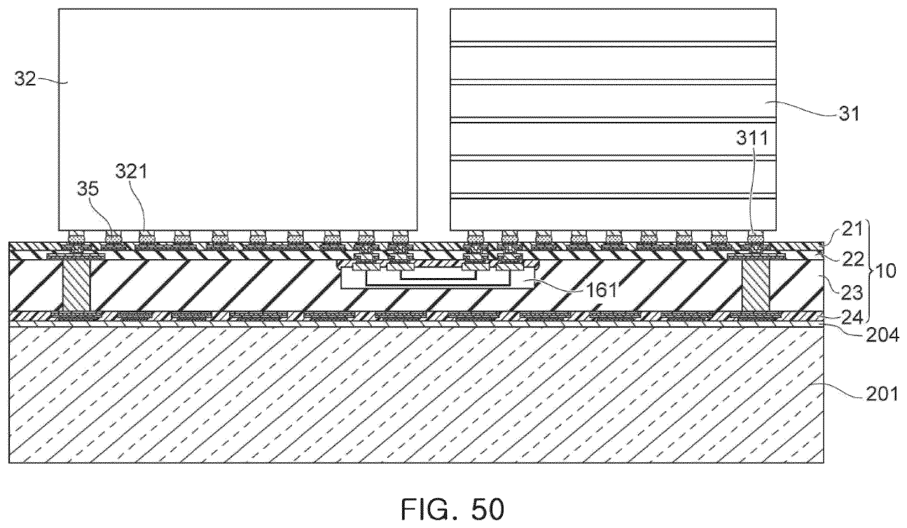

Next, a bump 35 is formed on the first substrate electrode 11 (FIG. 49). Subsequently, the semiconductor devices 31 and 32 are mounted in the electronic component embedded substrate 10 via the bump 35 interposed therebetween (FIG. 50). In detail, the electrodes 311 and 321 of the semiconductor devices 31 and 32 and the first substrate electrode 11 of the electronic component embedded substrate 10 are electrically connected via the bump 35 interposed therebetween.

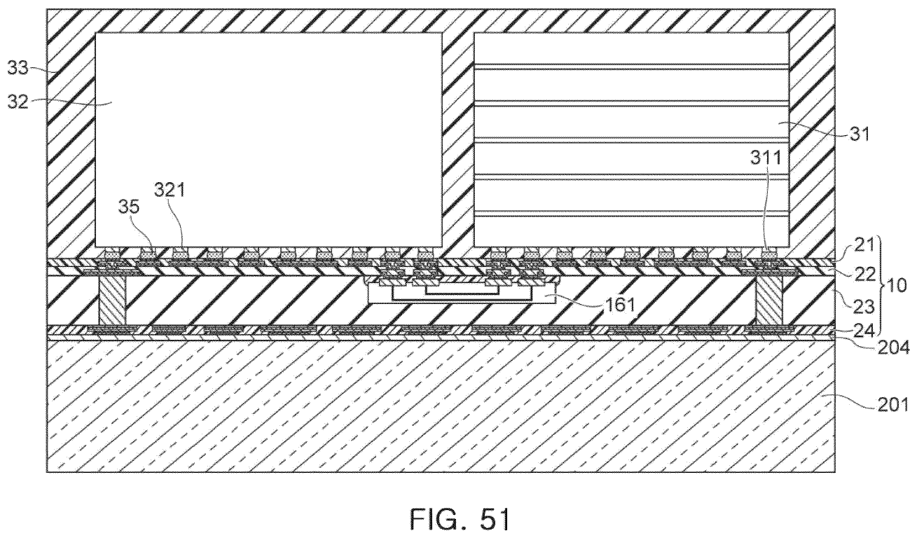

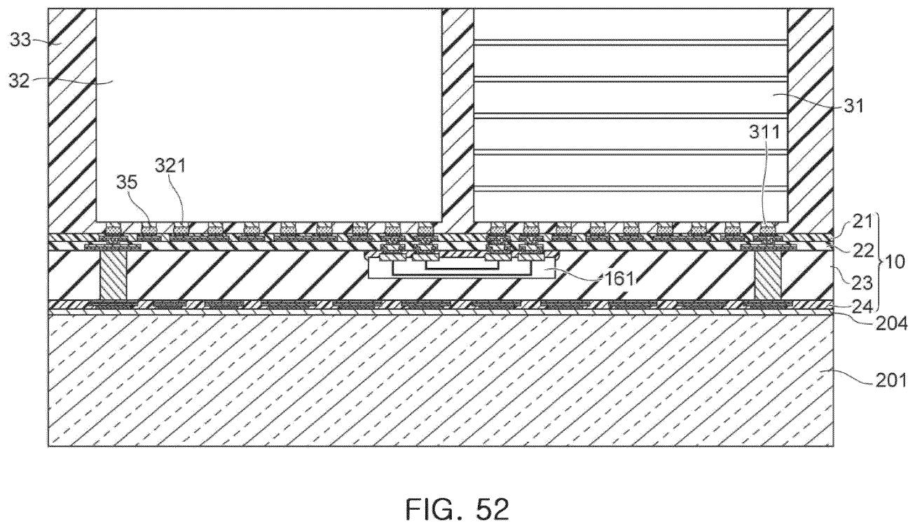

Next, an encapsulation layer 33 is formed to cover the semiconductor devices 31 and 32 (FIG. 51). Subsequently, the thickness of the encapsulation layer 33 is adjusted, for example, by polishing or the like (FIG. 52).

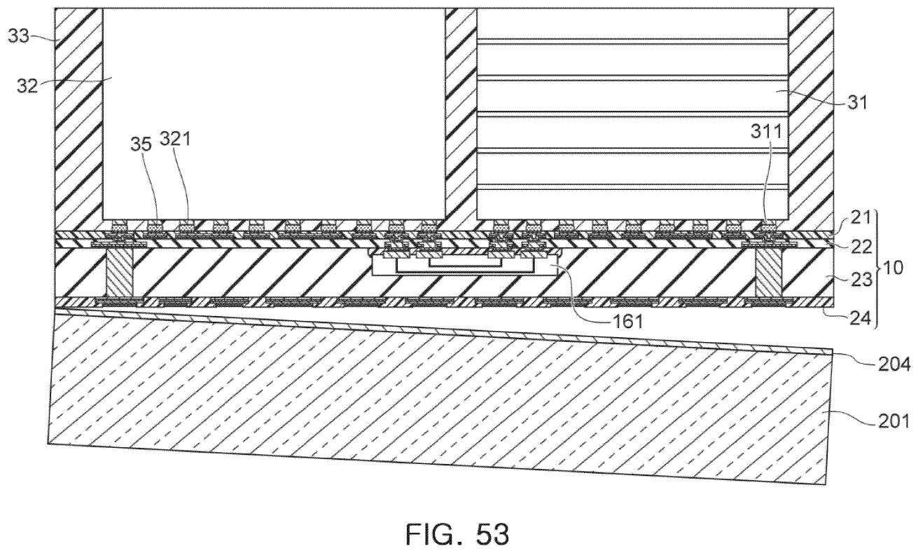

Next, the support 201 is removed (FIG. 53). For example, the support 201 is removed by peeling the support 201 from the electronic component embedded substrate 10. To remove the support 201, the same method as for removing the support 101 may be used.

Then, the mounting substrate 40 is connected to the electronic component embedded substrate 10. For example, the first electrode 43 of the mounting substrate 40 and the second substrate electrode 18 of the electronic component embedded substrate 10 are electrically connected through a bump 45 interposed therebetween. For example, an electronic device may be manufactured in this manner.

### (Operational Effect of Electronic Component Embedded Substrate 10)

In the electronic component embedded substrate 10 of the present example embodiment, because the seed layer 19 provided in the via hole V2 includes an adhesive film 191, the seed layer 19 easily adheres to the wall surface of the via hole V2.

For example, when the seed layer 19 does not include an adhesive film (for example, an adhesive film 191), the conductive film 192 comes into contact with the wall surface (e.g., side boundary) of the via hole V2. For example, when the conductive film 192 is composed of copper, the conductive film 192 has low adhesion to the adhesive layer 15, which is an organic insulating material, and thus the conductive film 192 is easily peeled off from the wall surface (e.g., side boundary) of the via hole V2. Due to the peeling off of the conductive film 192, there is a concern that a connection failure may occur between the terminal electrode 161 and the first conductive layer 13.

On the other hand, in the electronic component embedded substrate 10, because the conductive film 192 is formed in the via hole V2 by interposing the adhesive film 191 therein, the seed layer 19 is easily adhered to the wall surface (e.g., side boundary) of the via hole V2 compared to the case where the adhesive film 191 is not provided. Accordingly, the occurrence of a connection failure between the terminal electrode 161 and the first conductive layer 13 due to the peeling off of the seed layer 19 is suppressed. Therefore, connection reliability between conductors through the via hole V2 interposed therebetween may be improved.

Furthermore, by configuring the adhesive film 191 with titanium, the wall surface (e.g., side boundary) of the via hole V2 and the seed layer 19 become more easily in close contact. Therefore, occurrence of a connection failure between the terminal electrode 161 and the first conductive layer 13 may be more effectively suppressed.

As described above, in the electronic component embedded substrate 10 of the present example embodiment, because the seed layer 19 provided in the via hole V2 includes the adhesive film 191, the seed layer 19 becomes more easily in close contact with the wall surface of the via hole V2. Accordingly, the occurrence of a connection failure between the terminal electrode 161 and the first conductive layer 13 due to peeling of the seed layer 19 is suppressed. Therefore, connection reliability between conductors through the via hole V2 may be improved.

Hereinafter, a description will be given of a modified example of the electronic component embedded substrate 10 according to the above example embodiment. Hereinafter, to avoid duplication of explanation, a detailed description of the same configuration as the electronic component embedded substrate 10 of the above embodiment will be omitted.

### Modified Example

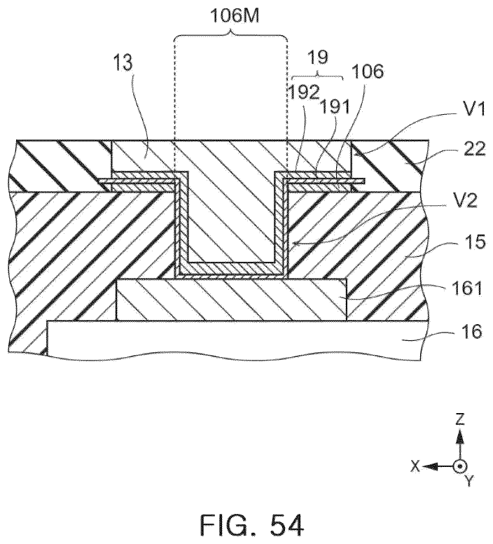

FIG. 54 illustrates an example of a configuration near a via hole V2 of an electronic component embedded substrate 10 according to a modified example. FIG. 54 corresponds to FIG. 2, which illustrate an electronic component embedded substrate 10 according to an example embodiment. The electronic component embedded substrate 10 has a second seed layer 106 on the surface of the adhesive layer 15. Except for this point, the electronic component embedded substrate 10 according to the modified example has the same configuration as the electronic component embedded substrate 10 described in the above example embodiment. In this case, the second seed layer 106 corresponds to a specific example of the metal film.

In the electronic component embedded substrate 10, a second seed layer 106, an adhesive film 191, and a conductive film 192 are disposed in order from the adhesive layer 15 side between the surface of the adhesive layer 15 and the first conductive layer 13.

The second seed layer 106 is provided with a through-hole 106M that is fluidly connected to the via hole V2. The second seed layer 106 includes a through-hole 106M defined therethrough. The through-hole 106M is provided by penetrating the second seed layer 106 in the thickness direction (Z-direction). The through-hole 106M is provided at a position overlapping the via hole V2 in a plane (X-Y plane). The through-hole 106M has a diameter that is almost the same as the hole diameter (diameter) of the via hole V2. The second seed layer 106 includes, for example, copper. The thickness of the second seed layer 106 is, for example, about 0.05 μm to about 5 μm.

The seed layer 19 is provided in the via hole V2 through the through-hole 106M defined by the surface of the second seed layer 106. For example, the seed layer 19 is also provided along the boundary of the through-hole 106M. For example, the seed layer 19 include a first portion on a surface of the metal film and a second portion connected to the first portion and being along a boundary of the through hole 106M and the boundary of the via hole V2. The adhesive film 191 is provided, for example, from the surface of the second seed layer 106 to the outer side of the edge of the second seed layer 106. The adhesive film 191 may be provided to protrude beyond the edge of the second seed layer 106, or may cover the edge of the second seed layer 106. The adhesive film 191 is formed of, for example, titanium.

The edge of the conductive film 192 constituting the seed layer 19 is provided, for example, at a position overlapping the edge of the second seed layer 106 in a plane (X-Y plane). The conductive film 192 is formed of, for example, copper.

The electronic component embedded substrate 10 according to the modified example is formed, for example, as follows. First, an opening H2 is formed in the same manner as described in the above example embodiment (FIG. 30). Thereafter, a seed layer 19 is formed without removing the second seed layer 106. Subsequently, the processes of FIGS. 31 to 36 are performed in the same manner as described in the above example embodiment. Next, the seed layer 19 exposed from/by the first conductive layer 13 is removed (FIG. 37), and then the second seed layer 106 exposed from/by the first conductive layer 13 is removed. At this time, for example, a part of the conductive film 192 is etched together with the second seed layer 106. Accordingly, the adhesive film 191 is formed outside of both of the edge of the conductive film 192 and the edge of the second seed layer 106. After removing the second seed layer 106 exposed from the first conductive layer 13, the processes of FIGS. 38 to 53 are performed in the same manner as described in the above example embodiment. For example, an electronic component embedded substrate 10 according to a modified example may be formed in this manner.

In the electronic component embedded substrate 10 according to a modified example, because the seed layer 19 provided in the via hole V2 includes an adhesive film 191, the seed layer 19 is easily adhered to the wall surface (e.g., side boundary) of the via hole V2. Accordingly, occurrence of a connection failure between the terminal electrode 161 and the first conductive layer 13 due to peeling of the seed layer 19 is suppressed. Accordingly, connection reliability between the conductors through the via hole V2 interposed therebetween may be improved.

In addition, in the electronic component embedded substrate 10, the removal process of the second seed layer 106 may not be needed. Accordingly, the number of manufacturing processes is reduced, and/or the yield may be improved. Furthermore, the second seed layer 106 includes a metal material such as copper, titanium, or chromium. Accordingly, the thermal conductivity near the via hole V2 is increased, and the heat dissipation of the electronic component embedded substrate 10 may be improved.

### Other Modified Examples

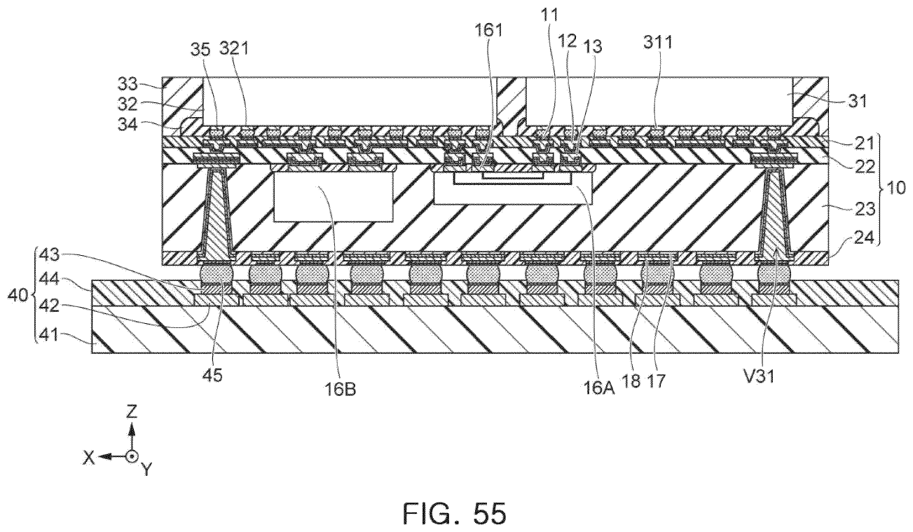

FIGS. 55 to 57 show examples of the configuration of an electronic component embedded substrate 10 according to other modified examples.

The electronic component embedded substrate 10 may have a via hole V31 instead of a pillar 14 (FIGS. 55 to 57).

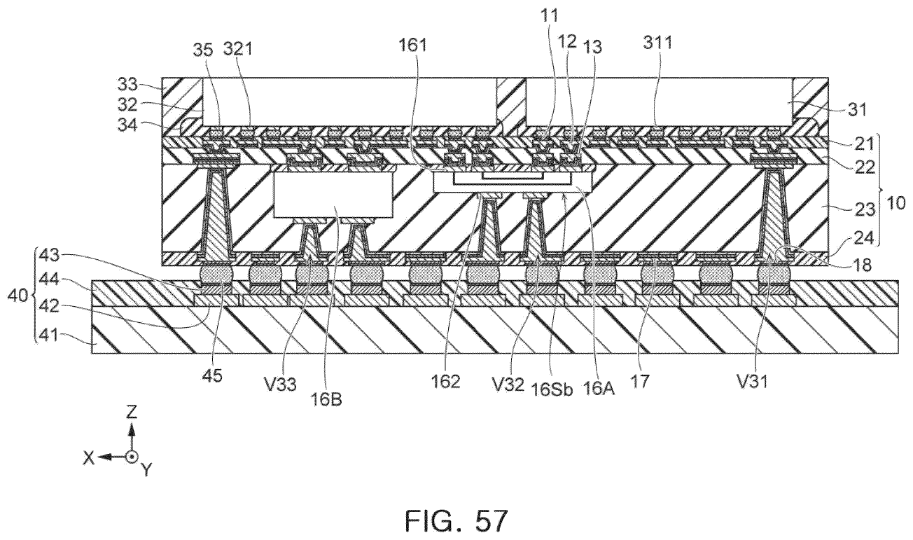

A plurality of electronic components (electronic components 16A and 16B) may be mounted in the electronic component embedded substrate 10 (FIGS. 55 and 57). These plurality of electronic components may have different thicknesses (sizes in the Z-direction). For example, by mounting a plurality of electronic components on a support substrate (for example, a support substrate 100 of FIG. 13) in a face-down manner, a plurality of electronic components with different thicknesses may be easily mounted in the electronic component embedded substrate 10 with relatively high alignment precision.

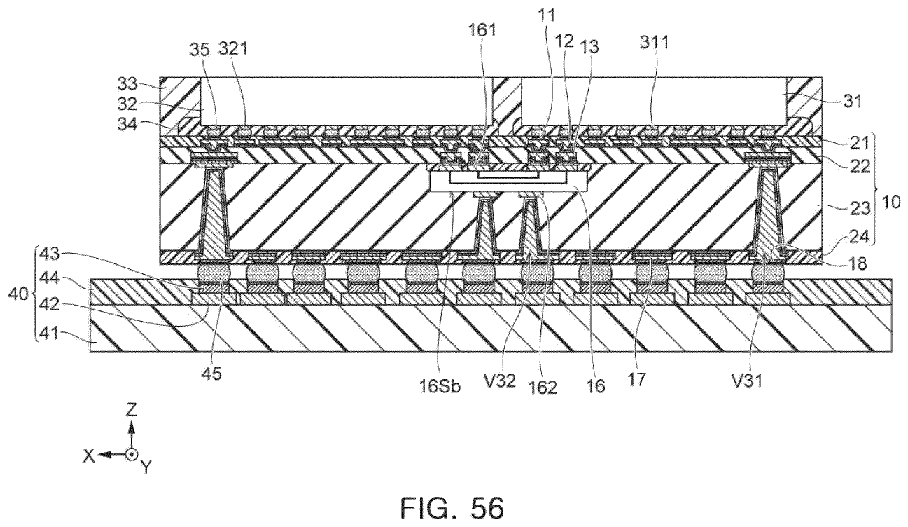

The electronic component 16 may additionally have a terminal surface 16Sb facing a terminal surface 16Sa (see FIG. 2) in the Z-direction (FIGS. 56 and 57). A terminal electrode 162 is provided on the terminal surface 16Sb. The terminal electrode 162 is electrically connected to the second conductive layer 17 via, for example, a via hole V32 formed therebetween. In this case, the terminal surface 16Sb corresponds to a specific example of the second terminal surface, and the terminal electrode 162 corresponds to a specific example of the second terminal electrode.

The electronic component embedded substrate 10 may have three or more electronic components.

FIG. 1 illustrates an example in which one terminal electrode 161 is provided with one via hole V2. A plurality of via holes V2 may be provided in one terminal electrode 161.

In FIGS. 3 to 53, an example of a manufacturing process of an electronic component embedded substrate 10 is illustrated, but an electronic component embedded substrate 10 may be manufactured through a process different therefrom. Other known methods may be used to form respective members.

The configuration of the electronic component embedded substrate 10 described above is a description of the main configuration in describing the features of the above-described example embodiment, and is not limited to the configuration described above, and may be modified in various ways within the scope of the patent claims. In addition, it does not exclude a configuration provided by a general electronic component embedded substrate.

Some example embodiments of the present inventive concepts will be described in more detail using the following examples and comparative examples, but the technical scope of the present inventive concepts is not limited to the following examples.

### <Fabrication of Electronic Component Embedded Substrate>

### Example 1

In the same manner as described in the above example embodiment, an electronic component embedded substrate having 15 electronic components was fabricated.

### Example 2

In the same manner as described in the above modified example, an electronic component embedded substrate having 15 electronic components was fabricated. In detail, the second seed layer 106 was left to fabricate an electronic component embedded substrate.

### COMPARATIVE EXAMPLE

Except for not forming the adhesive film 191 of the seed layer 19, an electronic component embedded substrate having 15 electronic components was fabricated in the same manner as in Example 1.

### <Evaluation of Electronic Component Embedded Substrate>

The connection reliability of the fabricated electronic component embedded substrate was evaluated using a reflow load test (IPC/J-STD-020D standard). The peak temperature of the reflow was 260 degrees. In the reflow load test, 15 electronic component embedded substrates of Example 1, Example 2, and Comparative Example were passed through the reflow furnace 10 times, respectively, and the number of electronic component embedded substrates in which open defects occurred was measured. The evaluation results of these electronic component embedded substrates are illustrated in Table 1 below.

TABLE 1

| | Number of Passes | | | | | |
|---|---|---|---|---|---|---|
| | 1 | 2 | 3 | 4 | 5 | 10 |
| Example 1 | 0/15 | 0/15 | 0/15 | 0/15 | 0/15 | 0/15 |
| Example 2 | 0/15 | 0/15 | 0/15 | 0/15 | 0/15 | 0/15 |
| Comparative | 0/15 | 1/15 | 12/15 | 15/15 | — | — |
| Example | | | | | | |

In the electronic component embedded substrate according to the comparative example, open defects occurred in all 15 substrates when passed through the reflow oven 4 times. In contrast, in the electronic component embedded substrates according to Examples 1 and 2, open defects did not occur in all 15 electronic component embedded substrates even when passed through the reflow oven 10 times. In this manner, it was confirmed that the electronic component embedded substrates according to Examples 1 and 2 had higher connection reliability than the electronic component embedded substrate according to the comparative example.

As set forth above, in an electronic component embedded substrate and a method of manufacturing an electronic component embedded substrate according to an example embodiment, because a seed layer provided in a via hole includes an adhesive film, the seed layer easily adheres to a wall surface of the via hole. Accordingly, occurrence of a connection failure between a first terminal electrode and a first conductive layer due to peeling of the seed layer may be suppressed. Accordingly, connection reliability between conductors with the via hole may interposed therebetween be improved.

While some example embodiments have been illustrated and described above, it will be apparent to those skilled in the art that modifications and variations could be made without departing from the scope of the present inventive concepts as defined by the appended claims.

What is claimed is:

1. An electronic component embedded substrate comprising:
at least one electronic component including a first terminal surface and a first terminal electrode, the first terminal electrode being on the first terminal surface;
a first conductive layer facing the first terminal surface;
an insulating layer between the first conductive layer and the first terminal surface, the insulating layer including a via hole penetrating therethrough, the first conductive layer filling the via hole and being connected to the first terminal electrode; and
a seed layer in the via hole, the seed layer including a conductive film and an adhesive film, the adhesive film being between the conductive film and a boundary of the via hole.

2. The electronic component embedded substrate of claim 1, further comprising:
a metal film between the first conductive layer and the insulating layer,
wherein the metal film includes a through-hole defined therethrough and fluidly connected to the via hole.

3. The electronic component embedded substrate of claim 2, wherein the seed layer is further provided in the through-hole.

4. The electronic component embedded substrate of claim 3, wherein the seed layer include:
a first portion on a surface of the metal film; and
a second portion connected to the first portion and being along a boundary of the through hole and the boundary of the via hole.

5. The electronic component embedded substrate of claim 4, wherein the adhesive film is provided from the surface of the metal film to an outer side of an edge of the metal film.

6. The electronic component embedded substrate of claim 1, wherein
the conductive film includes copper (Cu), and
the adhesive film includes titanium (Ti).

7. The electronic component embedded substrate of claim 1, wherein at least one of the conductive film or the adhesive film includes a sputter film.

8. The electronic component embedded substrate of claim 1, wherein the adhesive film defines the boundary of the via hole.

9. The electronic component embedded substrate of claim 1, wherein a diameter of the via hole is substantially uniform across a thickness direction of the insulating layer.

10. The electronic component embedded substrate of claim 1, wherein a thickness of each of the conductive film and the adhesive film increases towards the first terminal electrode.

11. The electronic component embedded substrate of claim 1, wherein the insulating layer includes an organic insulating material.

12. The electronic component embedded substrate of claim 1, wherein
the electronic component embedded substrate further comprises a second conductive layer,
the electronic component further includes a second terminal surface opposing the first terminal surface, and a second terminal electrode is on the second terminal surface, and
the second terminal electrode is electrically connected to the second conductive layer.

13. The electronic component embedded substrate of claim 1, wherein the at least one electronic component includes a plurality of electronic components.

14. The electronic component embedded substrate of claim 13, wherein the plurality of electronic components include electronic components having different thicknesses.

15. A method of manufacturing an electronic component embedded substrate, comprising:
providing an adhesive layer on a support substrate;
attaching an electronic component to the support substrate such that a terminal surface of the electronic component, which includes a terminal electrode thereon faces the support substrate with the adhesive layer interposed between the terminal surface and the support substrate facing each other;
removing the support substrate;
forming an opening in the adhesive layer to expose the terminal electrode therethrough;
forming an adhesive film and a conductive film in order to form a seed layer in the opening; and
forming a conductor electrically connected to the terminal electrode via the seed layer.

16. The method of claim 15, wherein
the providing the adhesive layer includes providing the adhesive layer interposing a metal film on the support substrate, and
the forming the opening includes forming a through-hole in the metal film such that the opening is fluidly connected to the through-hole.

17. The method of claim 15, wherein the forming the adhesive film and the conductive film includes forming the adhesive film and the conductive film using a sputtering method.

18. The method of claim 15, wherein the forming the opening includes forming the opening in the adhesive layer using a dry etching method.
